(19) United States
(12) Patent Application Publication
(10) Pub. No.: US 2026/0348038 A1
(43) Pub. Date: Nov. 5, 2026

(54) Compositions and Methods for Electrochemical Metallic Plating

(71) Applicant: Moses Lake Industries, Inc., Moses Lake, WA (US)

(72) Inventors: Yukihiro Hara, Moses Lake, WA (US); Michael Webb, Moses Lake, WA (US); Eric Webb, Moses Lake, WA (US)

(73) Assignee: Moses Lake Industries, Inc., Moses Lake, WA (US)

(21) Appl. No.: 19/657,447

(22) Filed: Apr. 24, 2026

Related U.S. Application Data
(60) Provisional application No. 63/794,027, filed on Apr. 24, 2025.
(60) Provisional application No. 63/817,693, filed on Jun. 4, 2025.

(51) Int. Cl. C25D 3/38; C22F 1/08; C25D 5/50; C25D 7/12; H05K 3/42

(52) U.S. Cl. CPC C25D 3/38; C22F 1/08; C25D 5/50; C25D 7/12; H05K 3/424

(57) ABSTRACT

Compositions and methods for the grain engineering of electroplated copper are disclosed. An electroplating solution may include a virgin makeup (VMS) solution including Copper (Cu) ions (A-1), sulfuric acid (H₂SO₄) (A-2), and chloride ions (A-3). The electroplating solution may also include one or more additives including a suppressor (B), an accelerator (C), a bromine solution (D), and optionally a leveler (E). The bromine solution may include sodium bromide (NaBr) (D-1), sulfuric acid (H₂SO₄) (D-2), and copper sulfate (CuSO₄) (D-3).

### CROSS-REFERENCE TO RELATED APPLICATION(S)

This application claims the priority benefit, under 35 U.S.C. 119(e), of U.S. Application No. 63/794,027, filed Apr. 24, 2025, and entitled, “Compositions and Methods for Electrochemical Metallic Plating,” and U.S. Application No. 63/817,693, filed Jun. 4, 2025, and entitled, “Compositions and Methods for Electrochemical Metallic Plating.” Each of the aforementioned applications is incorporated herein by reference in its entirety.

### BACKGROUND

Copper (Cu) electroplating is the process of electroplating a layer of copper onto the surface of a metal object using an electric current and an electrolyte solution. Electrodeposited copper can also be utilized for via-filling, for example vias in the substrate of a printed circuit board (PCB) in semiconductor device manufacturing. Copper electroplating can also be used as part of the process to connect multiple semiconductor dies as part of advanced packaging.

A common method for advanced packaging involves using a flip chip packaging process that connects the semiconductor dies with the use of a thermal bump that is capped with a solder material (e.g., a tin (Sn) and silver (Ag) alloy). However, as the contact pitch of devices continues to be reduced this method becomes problematic. As an alternative to using thermal bumps, Cu to Cu hybrid bonding may be used. Cu to Cu hybrid bonding allows for direct connection of exposed Cu pads after the chemical mechanical polishing (CMP) of two semiconductor dies using chemical bonding of exposed silicon dioxide (SiO₂), polymer, and/or glass surfaces. After annealing at low to moderate temperatures, the two Cu surfaces may combine through grain growth to eliminate any interface. However, being able to control the growth of the grains of the Cu films may impact the success of the Cu to Cu bond. Thus, there remains a need for methods and compositions that allow for the control of grain growth in Cu films in semiconductor device manufacturing.

### SUMMARY

In some aspects, the techniques described herein relate to a method of making a film of electrodeposited copper on a substrate, the method including immersing the substrate in an electroplating solution including a virgin makeup solution including a source of copper ions, sulfuric acid, and a source of chloride ions, a suppressor, an accelerator, and a source of bromine ions, and applying a current density to the electroplating solution, wherein the film of electrodeposited copper has a concentration of bromine ions of about 0.2 ppm to about 250 ppm, a first crystal plane orientation of (111) and (200), and a first grain size of about 5 nm to about 500 nm.

In some aspects, the techniques described herein relate to a method, wherein the first grain size is about 1 nm to about 500 nm.

In some aspects, the techniques described herein relate to a method, further including annealing the film of electrodeposited copper for a period of time at a temperature of about 150 °C to about 350 °C, wherein the annealed film of electrodeposited copper has a second crystal plane orientation of (111) and (200) and a second grain size that is larger than the first grain size.

In some aspects, the techniques described herein relate to a method, wherein the second grain size is greater than 1 μm.

In some aspects, the techniques described herein relate to a method, wherein the period of time is at least one hour.

In some aspects, the techniques described herein relate to a method, wherein the film of electrodeposited copper is a copper metal pad.

In some aspects, the techniques described herein relate to a method, wherein the film of electrodeposited copper is a first film of electrodeposited copper, the method further including making a second film of electrodeposited copper, wherein the first film of electrodeposited copper is a first copper metal pad and the second film of electrodeposited copper is a second copper metal pad and bonding the first film of electrodeposited copper and the second film of electrodeposited copper at an annealing temperature of about 150 °C to about 350 °C for a period of time, wherein there is no interface between the first copper metal pad and the second copper metal pad following the bonding.

In some aspects, the techniques described herein relate to a method, wherein the substrate includes a copper seed layer disposed on the substrate.

In some aspects, the techniques described herein relate to a method, wherein the film of electrodeposited copper is disposed on top of the copper seed layer.

In some aspects, the techniques described herein relate to a method, wherein the concentration of bromine ions in the film of electrodeposited copper is about 0.6 ppm to about 230 ppm.

In some aspects, the techniques described herein relate to a method, wherein the concentration of bromine ions in the film of electrodeposited copper is about 1 ppm to about 210 ppm.

In some aspects, the techniques described herein relate to a method, wherein the source of bromine ions is present in the electroplating solution in an amount of about 10 ppm to about 100 ppm.

In some aspects, the techniques described herein relate to a method, wherein the source of bromine ions is present in the electroplating solution in an amount of 20 ppm to about 70 ppm.

In some aspects, the techniques described herein relate to a method, wherein the sulfuric acid is present in the virgin makeup solution in a concentration of about 10 g/L to about 200 g/L.

In some aspects, the techniques described herein relate to a method, wherein the source of source of bromine ions includes a bromine solution including sodium bromide, sulfuric acid, present in the bromine solution in a concentration of about 1 g/L to about 10 g/L, and copper sulfate.

In some aspects, the techniques described herein relate to a method, wherein the sodium bromide is present in the bromine solution in a concentration of about 0.1 g/L to about 1.5 g/L and the copper sulfate is present in the bromine solution in a concentration of about 50 mg/L to about 5 g/L.

In some aspects, the techniques described herein relate to a method, wherein the film of electrodeposited copper is used for hybrid bonding.

In some aspects, the techniques described herein relate to a copper metal pad for hybrid bonding, the copper metal pad including a concentration of bromine ions of about 0.2 ppm to about 250 ppm.

In some aspects, the techniques described herein relate to a copper metal pad, further including a combination of a crystal plane orientation of (111) and (200).

In some aspects, the techniques described herein relate to a copper metal pad, wherein the crystal plane orientation is (111) and (200) following annealing of the copper metal pad.

In some aspects, the techniques described herein relate to a copper metal pad, wherein the copper metal pad has a first crystal plane orientation ratio of (111)/(200) before annealing and a second crystal plane orientation ratio of (111)/(200) following annealing.

In some aspects, the techniques described herein relate to a copper metal pad, wherein the first crystal plane orientation ratio is different from the second crystal plane orientation ratio.

In some aspects, the techniques described herein relate to a copper metal pad, further including a grain size of about 5 nm to about 500 nm.

In some aspects, the techniques described herein relate to a copper metal pad, wherein the grain size is about 1 nm to about 500 nm.

In some aspects, the techniques described herein relate to a copper metal pad, wherein the grain size increases following annealing at a temperature of about 150 °C to about 350 °C.

In some aspects, the techniques described herein relate to a copper metal pad, wherein the grain size following annealing is greater than 1 μm.

In some aspects, the techniques described herein relate to a copper metal pad, wherein the copper metal pad is a first copper metal pad and further including a second copper metal pad contacting the first copper metal pad following the annealing, wherein there is no interface between the first copper metal pad and the second copper metal pad following the annealing.

In some aspects, the techniques described herein relate to a copper metal pad, wherein the copper metal pad is connected to a plurality of interconnections on a substrate.

In some aspects, the techniques described herein relate to a copper metal pad, wherein the copper metal pad is embedded between one or more insulator areas.

In some aspects, the techniques described herein relate to a copper metal pad, wherein the substrate includes a wafer, a die, or a chip.

In some aspects, the techniques described herein relate to a copper metal pad, wherein the substrate is a first substrate and wherein the copper metal pad forms part of a vertical bond between the first substrate and a second substrate stacked vertically above the first substrate.

In some aspects, the techniques described herein relate to a method of making a film of electrodeposited copper on a substrate, the method including immersing the substrate in an electroplating solution including a virgin makeup solution including a source of copper ions, sulfuric acid, and a source of chloride ions, a weak suppressor, an accelerator, present in the electroplating solution in an amount of about 10 ppm to about 60 ppm, and a bromine solution including a source of bromine ions, present in the electroplating solution in an amount of about 10 ppm to about 100 ppm, sulfuric acid, and copper sulfate, and applying a current density to the electroplating solution.

In some aspects, the techniques described herein relate to a method, wherein the source of bromine ions is present in the electroplating solution in an amount of about 20 ppm to about 70 ppm.

In some aspects, the techniques described herein relate to a method, wherein sulfuric acid is present in the bromine solution in a concentration of about 1 g/L to about 10 g/L.

In some aspects, the techniques described herein relate to a method, wherein sulfuric acid is present in the bromine solution in a concentration of about 4 g/L to about 6 g/L.

In some aspects, the techniques described herein relate to a method, wherein copper sulfate is present in the bromine solution in a concentration of about 50 mg/L to about 5 g/L.

In some aspects, the techniques described herein relate to a method, wherein the substrate includes a layer of copper disposed on the substrate.

In some aspects, the techniques described herein relate to a method, wherein the layer of copper on the substrate includes a copper seed layer.

In some aspects, the techniques described herein relate to a method, wherein the film of electrodeposited copper is disposed on top of the layer of copper.

In some aspects, the techniques described herein relate to a method, further including annealing the film of electrodeposited copper for a period of time at a temperature of about 150 °C to about 350 °C and increasing a grain size of the electrodeposited copper following the annealing.

In some aspects, the techniques described herein relate to a method, wherein the film of electrodeposited copper is a copper metal pad.

In some aspects, the techniques described herein relate to a method, wherein the copper metal pad has a concentration of bromine ions of about 0.2 ppm to about 250 ppm and a grain size of at least 1 μm.

In some aspects, the techniques described herein relate to a method, wherein the film of electrodeposited copper is used for hybrid bonding.

In some aspects, the techniques described herein relate to a method, wherein the sulfuric acid is present in the virgin makeup solution in a concentration of about 10 g/L to about 200 g/L.

In some aspects, the techniques described herein relate to a hybrid bonded device, the hybrid bonded device including a first substrate and a second substrate, a plurality of first copper metal pads on the first substrate and disposed between the first substrate and the second substrate, the plurality of first copper metal pads separated by a plurality of first insulator layers, a plurality of second copper metal pads on the second substrate and disposed between the first substrate and the second substrate, the plurality of second copper metal pads separated by a plurality of second insulator layers, wherein each of the plurality of first copper metal pads and the plurality of second copper metal pads have a concentration of bromine ions of about 0.2 ppm to about 250 ppm, the plurality of first copper metal pads are bonded to the plurality of second copper metal pads following annealing at a temperature of about 150 °C to about 350 °C for a period of time and there is no interface between the plurality of first copper metal pads and the plurality of second copper metal pads following annealing.

In some aspects, the techniques described herein relate to a hybrid bonded device, wherein each of the plurality of first copper metal pads and the plurality of second copper metal pads have a first combination of a crystal plane orientation of (111) and (200) with a first crystal plane orientation ratio of (111)/(200).

In some aspects, the techniques described herein relate to a hybrid bonded device, wherein each of the plurality of first copper metal pads and the plurality of second copper metal pads have a second combination of a crystal plane orientation of (111) and (200) with a second crystal plane orientation ratio of (111)/(200) following annealing of the hybrid bonded device.

In some aspects, the techniques described herein relate to a hybrid bonded device, wherein the first crystal plane orientation ratio is different from the second crystal plane orientation ratio.

In some aspects, the techniques described herein relate to a hybrid bonded device, wherein each of the plurality of first copper metal pads and the plurality of second copper metal pads have a grain size of about 5 nm to about 500 nm.

In some aspects, the techniques described herein relate to a hybrid bonded device, wherein the grain size is about 1 nm to about 500 nm.

In some aspects, the techniques described herein relate to a hybrid bonded device, wherein the grain size increases following annealing at a temperature of about 150 °C to about 350 °C.

In some aspects, the techniques described herein relate to a hybrid bonded device, wherein the grain size following annealing is greater than 1 μm.

In some aspects, the techniques described herein relate to a hybrid bonded device, wherein the period of time is at least one hour.

In some aspects, the techniques described herein relate to a hybrid bonded device, further including a plurality of first interconnections on the first substrate and disposed between the first substrate and the plurality of first copper metal pads and a plurality of second interconnections on the second substrate and disposed between the second substrate and the plurality of second copper metal pads.

In some aspects, the techniques described herein relate to a first additive for an electroplating solution to facilitate electrodeposition of copper on a substrate, the electroplating solution including a virgin makeup solution including a source of copper ions, sulfuric acid, and a source of chloride ions, and the first additive including a source of bromine ions, sulfuric acid, and copper sulfate, wherein, the first additive is to be used with a second additive including a weak suppressor to interact with the chloride ions, facilitate adsorption to a surface of the substrate and decelerate plating kinetics of the electrodeposition of copper, and a third additive including an accelerator to displace the second additive to accelerate the plating kinetics of the electrodeposition of copper.

In some aspects, the techniques described herein relate to a first additive for an electroplating solution, wherein a concentration of the bromine ions in the electroplating solution is about 5 ppm to about 200 ppm.

In some aspects, the techniques described herein relate to a first additive for an electroplating solution, wherein the concentration of the bromine ions in the electroplating solution is about 10 ppm to about 100 ppm.

In some aspects, the techniques described herein relate to a first additive for an electroplating solution, wherein the source of bromine ions includes sodium bromide.

In some aspects, the techniques described herein relate to a first additive for an electroplating solution, wherein the sulfuric acid in the first additive has a concentration of about 1 g/L to about 10 g/L.

In some aspects, the techniques described herein relate to a first additive for an electroplating solution, wherein the sulfuric acid in the first additive has a concentration of about 4 g/L to about 6 g/L.

In some aspects, the techniques described herein relate to a first additive for an electroplating solution, wherein sulfuric acid is present in the virgin makeup solution in a concentration of about 10 g/L to about 200 g/L.

In some aspects, the techniques described herein relate to an electroplating solution to facilitate electrodeposition of copper on a substrate, the electroplating solution including a virgin makeup solution including a source of copper ions, sulfuric acid, and a source of chloride ions, a weak suppressor, an accelerator, present in the electroplating solution in an amount of about 10 ppm to about 60 ppm, and a bromine solution including a source of bromine ions, present in the electroplating solution in an amount of about 10 ppm to about 100 ppm, sulfuric acid, and copper sulfate.

In some aspects, the techniques described herein relate to an electroplating solution, wherein the electroplating solution does not include a leveler.

In some aspects, the techniques described herein relate to an electroplating solution, wherein the sulfuric acid in the bromine solution has a concentration of about 1 g/L to about 10 g/L.

In some aspects, the techniques described herein relate to an electroplating solution, the sulfuric acid in the virgin makeup solution has a concentration of about 10 g/L to about 200 g/L.

In some aspects, the techniques described herein relate to a kit for an electroplating solution to facilitate electrodeposition of copper on a substrate, the kit including a first additive including a suppressor, a second additive including an accelerator, a third additive including a bromine solution, wherein the bromine solution includes a source of bromine ions, sulfuric acid, and copper sulfate, and instructions for using the first additive, the second additive, and the third additive with a virgin makeup solution (VMS) to make the electroplating solution to facilitate the electrodeposition of copper on the substrate.

In some aspects, the techniques described herein relate to a kit, further including the VMS, the VMS including a source of copper ions, sulfuric acid, a source of chloride ions, and instructions for using the first additive, the second additive, the third additive, and the VMS to make the electroplating solution to facilitate the electrodeposition of copper on the substrate.

In some aspects, the techniques described herein relate to a kit, wherein the sulfuric acid in the VMS has a concentration of about 10 g/L to about 200 g/L.

In some aspects, the techniques described herein relate to a film of electrodeposited copper on a substrate, the film including a concentration of bromine ions of about 0.2 ppm to about 250 ppm.

In some aspects, the techniques described herein relate to a film of electrodeposited copper, further including a combination of a crystal plane orientation of (111) and (200).

In some aspects, the techniques described herein relate to a film of electrodeposited copper, wherein the crystal plane orientation is of (111) and (200) following annealing of the film.

In some aspects, the techniques described herein relate to a film of electrodeposited copper, wherein the film of electrodeposited copper has a first crystal plane orientation ratio of (111)/(200) before annealing and a second crystal plane orientation ratio of (111)/(200) following annealing.

In some aspects, the techniques described herein relate to a film of electrodeposited copper, wherein the first crystal plane orientation ratio is different from the second crystal plane orientation ratio.

In some aspects, the techniques described herein relate to a film of electrodeposited copper, further including a grain size of about 5 nm to about 500 nm.

In some aspects, the techniques described herein relate to a film of electrodeposited copper, wherein the grain size is about 1 nm to about 500 nm.

In some aspects, the techniques described herein relate to a film of electrodeposited copper, wherein the grain size increases following annealing at a temperature of about 150 °C to about 350 °C.

In some aspects, the techniques described herein relate to a film of electrodeposited copper, wherein the grain size following annealing is greater than 1 μm.

In some aspects, the techniques described herein relate to a film of electrodeposited copper, wherein the film of electrodeposited copper is used in hybrid bonding.

In some aspects, the techniques described herein relate to an additive for an electroplating solution to facilitate electrodeposition of copper on a substrate, the additive including sodium bromide present in the additive in an amount of about 0.7 g/L to about 1.0 g/L, sulfuric acid present in the additive in an amount of about 4 g/L to about 6 g/L, and copper sulfate to provide a concentration of Cu ions, wherein the concentration of Cu ions in the additive is about 300 mg/L to about 800 mg/L.

In some aspects, the techniques described herein relate to an additive, wherein the additive has a pH of about 1.7 to about 2.

In some aspects, the techniques described herein relate to an additive, wherein pH is about 1.9.

In some aspects, the techniques described herein relate to a kit, including the additive, a suppressor, and an accelerator.

In some aspects, the techniques described herein relate to an additive, wherein the additive is to be used with a virgin makeup (VMS) solution including a source of copper ions, sulfuric acid, and a source of chloride ions.

In some aspects, the techniques described herein relate to an additive, in combination with the VMS solution.

In some aspects, the techniques described herein relate to an additive, wherein the sulfuric acid in the VMS solution has a concentration of about 10 g/L to about 200 g/L.

In some aspects, the techniques described herein relate to an additive, wherein the additive is to be used with the VMS solution and a suppressor and an accelerator to provide the electroplating solution to facilitate the electrodeposition of copper on the substrate.

In some aspects, the techniques described herein relate to an additive, in combination with the VMS solution, the suppressor, and the accelerator.

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 shows an illustration of copper electrodeposition for electrical interconnects.

FIG. 2 shows an experimental set up for electroplating copper.

FIG. 3A shows a schematic of grain and grain boundaries.

FIG. 3B shows a scanning electron microscopy image of a focused ion beam polished sample, providing an example grain structure of a plated Cu film with large grains.

FIG. 3C shows a scanning electron microscopy image of a focused ion beam polished sample, providing an example grain structure of a plated Cu film with columnar large grains.

FIG. 3D shows a scanning electron microscopy image of a focused ion beam polished sample, providing an example grain structure of a plated Cu film with oriented random large grains.

FIG. 4A shows a scanning electron microscopy image of a focused ion beam polished sample, providing an example grain structures of plated Cu films with fine grains.

FIG. 4B shows another scanning electron microscopy image of a focused ion beam polished sample, providing an example grain structures of plated Cu films with fine grains.

FIG. 4C shows a scanning electron microscopy image of a focused ion beam polished sample, providing an example grain structures of plated Cu films with a mix of fine grains and large grains.

FIG. 4D shows another scanning electron microscopy image of a focused ion beam polished sample, providing an example grain structures of plated Cu films with fine grains.

FIG. 5A shows scanning electron microscopy images of focused ion beam polished samples for a large grain plated Cu film (left, #1) and small grain plated Cu films (middle, #2, and right, #3).

FIG. 5B shows a graph illustrating the relationship between hardness and grain structure for the samples shown in FIG. 5A for a large grain plated Cu film (left, #1) and small grain plated Cu films (middle, #2, and right, #3).

FIG. 6 shows scanning electron microscopy images of focused ion beam polished samples, providing example grain structures of plated Cu films with varying amounts of Component (B) and constant amounts of Components (C) and (D).

FIG. 7A shows scanning electron microscopy images of focused ion beam polished samples, providing an example of fill behavior for plated Cu films in a 5×5 μm trench for varying concentrations of Component (C) with a fixed amount of Components (B) (D).

FIG. 7B shows scanning electron microscopy images of focused ion beam polished samples, providing an example of fill behavior for plated Cu films in a 5×5 μm trench for varying concentrations of Component (B) with a fixed amount of Components (C) and (D).

FIG. 7C shows scanning electron microscopy images of focused ion beam polished samples, providing an example of fill behavior for plated Cu films in a 5×5 μm trench for varying concentrations of Component (B) with a fixed and increased amount of Component (C) and a fixed amount of Component (D).

FIG. 8A shows scanning electron microscopy images of focused ion beam polished sample of a large grain Cu film (#1), providing example grain structures of the plated Cu film and the hardness values before (top image) and after annealing (bottom image).

FIG. 8B shows scanning electron microscopy images of focused ion beam polished sample of a fine grain Cu film (#2), providing example grain structures of the plated Cu film and the hardness values before (top image) and after annealing (bottom image).

FIG. 8C shows scanning electron microscopy images of focused ion beam polished sample of another fine grain Cu film (#3), providing example grain structures of the plated Cu film and the hardness values before (top image) and after annealing (bottom image).

FIG. 9 shows X-ray Diffraction (XRD) analysis and crystal plane orientation of plated Cu films 2 and 3 (right images) before and after annealing and scanning electron microscopy images of Cu films 2 and 3 from FIGS. 8B and 8C.

FIG. 10 shows a comparison of hardness (HV) without annealing and following annealing at 250 °C for 60 minutes for Components B1-B8.

FIG. 11A shows scanning electron microscopy images of focused ion beam polished samples, providing an example of grain structures of plated Cu films with increasing concentration of Component (C) and with Component (B1). The tests were performed at 3 amperes per square decimeter (ASD) with an anneal temperature of 250 °C.

FIG. 11B shows scanning electron microscopy images of focused ion beam polished samples, providing an example of grain structures of plated Cu films with increasing concentration of Component (C) and with Components (B2). The tests were performed at 3 amperes per square decimeter (ASD) with an anneal temperature of 250 °C.

FIG. 12A shows scanning electron microscopy images of focused ion beam polished samples, providing an example of via filling capability of grain engineered copper with 10 mL/L of Component (B1), 6 mL/L of Component (C), and 9 mL/L of Component (D). Plating was done at 3ASD.

FIG. 12B shows scanning electron microscopy images of focused ion beam polished samples, providing an example of via filling capability of grain engineered copper with 10 mL/L of Component (B2), 1 mL/L of Component (C), and 5.6 mL/L of Component (D). Plating was done at 3ASD.

FIG. 13A shows a Transmission Kikuchi Diffraction (TKD) image providing an example of the grain boundaries of stable fine grain engineered copper.

FIG. 13B shows a TKD image of providing an example of the grain boundaries of meta-stable fine grain engineered copper.

FIG. 14A shows a two-dimensional grain orientation map taken by TKD of the grain boundaries of stable fine grain engineered copper from FIG. 13A.

FIG. 14B shows a two-dimensional grain orientation map taken by TKD of the grain boundaries of meta-stable fine grain engineered copper from FIG. 13B.

FIG. 15A is a graph showing the grain size distribution of stable fine grain engineered copper.

FIG. 15B is a graph showing the grain size distribution of meta-stable fine grain engineered copper.

FIG. 15C is a graph showing the percentile grain size distribution of stable fine grain engineered copper.

FIG. 15D is a graph showing the percentile grain size distribution of meta-stable fine grain engineered copper.

FIG. 15E is a chart showing quantiles and summary statistics of stable fine grain engineered copper.

FIG. 15F is a chart showing quantiles and summary statistics of meta-stable fine grain engineered copper.

FIG. 16A shows a two-dimensional orientation map taken by TKD of the grain size distribution of grain engineered copper as plated.

FIG. 16B shows graphs of grain size distribution and percentile grain size distribution and charts of quantiles and summary statistics of grain engineered copper as plated.

FIG. 16C shows a two-dimensional orientation map taken by TKD of the grain boundaries of grain engineered copper after annealing at 250 °C for one hour.

FIG. 16D shows graphs of grain size distribution and percentile grain size distribution and charts of quantiles and summary statistics of grain engineered copper after annealing at 250 °C for one hour.

FIG. 17 is an image showing unoriented dispersion (UD).

FIG. 18 is a graph showing the thermal expansion of high thermal expansion coefficient (TEC) copper and conventional copper.

FIG. 19 is a graph showing the variation of contact area with annealing temperature for circular pads, dishing depth 4 nm (triangle), 5 nm (square), and 10 nm (circle). Conventional copper values are drawn as dashed line and TEC copper is shown with the solid line. Illustration of contact area between upper and lower copper pads.

FIG. 20 is an illustration of additive role in high TEC copper electrodeposition bath.

FIG. 21 is an illustration of the coefficient of thermal expansion (CTE) measuring method using C-Therm Tal.

FIG. 22A is a graph showing the change in length as a function of temperature for conventional copper, grain engineered fine grain copper (FG-Cu), and grain engineered thermal dynamic copper (TD-Cu). The FG-Cu and TD-Cu were plated using a plating bath including 10 mL/L of Component (B2), 1 mL/L of Component (C), and 6.5 mL/L of Component (D). The current densities for plating were 10 mA/cm² (TD-Cu), 30 mA/cm² (FG-Cu), and 40 mA/cm² (conventional copper).

FIG. 22B is a graph showing the CTE as a function of temperature for conventional copper, grain engineered fine grain copper (FG-Cu), and grain engineered thermal dynamic copper (TD-Cu). The FG-Cu and TD-Cu were plated using a plating bath including 10 mL/L of Component (B2), 1 mL/L of Component (C), and 6.5 mL/L of Component (D). The current densities for plating were 10 mA/cm² (TD-Cu), 30 mA/cm² (FG-Cu), and 40 mA/cm² (conventional copper).

FIG. 23A is a graph showing the change in length and CTE as a function of temperature for grain engineered fine grain copper (FG-Cu). The FG-Cu was plated using a plating bath including 10 mL/L of Component (B2), 1 mL/L of Component (C), and 6.5 mL/L of Component (D) and a current density of 30 mA/cm².

FIG. 23B is a graph showing the change in length and CTE as a function of temperature for grain engineered thermal dynamic copper (TD-Cu). The TD-Cu was plated using a plating bath including 10 mL/L of Component (B2), 1 mL/L of Component (C), and 6.5 mL/L of Component (D) and a current density of 10 mA/cm².

FIG. 23C is a graph showing the change in length and CTE as a function of temperature for conventional copper. The conventional copper was plated with a current density of 40 mA/cm².

FIG. 24A is a graph showing the change in length and CTE as a function of temperature for grain engineered thermal dynamic copper (TD-Cu) after plating at 5.7 mA/cm². The plating bath included 40 g/L Cu (A-1), 10 g/L sulfuric acid (A-2), 50 ppm Cl (A-3), 10 mL/L of Component (B2), 1 mL/L of Component (C), and 6.5 mL/L of Component (D).

FIG. 24B is a graph showing the change in length and CTE as a function of temperature for grain engineered thermal dynamic copper (TD-Cu) after plating at 8.5 mA/cm². The plating bath included 40 g/L Cu (A-1), 10 g/L sulfuric acid (A-2), 50 ppm Cl (A-3), 10 mL/L of Component (B2), 1 mL/L of Component (C), and 6.5 mL/L of Component (D).

FIG. 24C is a graph showing the change in length and CTE as a function of temperature for grain engineered thermal dynamic copper (TD-Cu) after plating at 14.2 mA/cm². The plating bath included 40 g/L Cu (A-1), 10 g/L sulfuric acid (A-2), 50 ppm Cl (A-3), 10 mL/L of Component (B2), 1 mL/L of Component (C), and 6.5 mL/L of Component (D).

FIG. 25A is a graph showing the change in length and CTE as a function of temperature for grain engineered fine grain copper (FG-Cu) after plating at 30 mA/cm². The plating bath included 10 g/L Cu (A-1), 10 g/L sulfuric acid (A-2), 50 ppm Cl (A-3), 10 mL/L of Component (B2), 1 mL/L of Component (C), and 6.5 mL/L of Component (D).

FIG. 25B is a graph showing the change in length and CTE as a function of temperature for grain engineered thermal dynamic copper (TD-Cu) after plating at 10 mA/cm². The plating bath included 10 g/L Cu (A-1), 10 g/L sulfuric acid (A-2), 50 ppm Cl (A-3), 10 mL/L of Component (B2), 1 mL/L of Component (C), and 6.5 mL/L of Component (D).

FIG. 26 shows the results of hardness by nanoindentation for grain engineered fine grain copper (FG-Cu) compared to conventional copper controls plated at a thickness of 30 μm and 7 μm before and after annealing at 230 °C.

FIG. 27A shows a schematic of hybrid bonding with copper interconnects.

FIG. 27B shows a schematic of hybrid bonding without copper interconnects.

FIG. 28A shows a schematic of hybrid bonding with conventional copper pads.

FIG. 28B shows a schematic of hybrid bonding with grain engineered copper pads.

FIG. 29 shows a flow chart for an example method of making a film of electrodeposited copper.

FIG. 30 shows a flow chart for an example method of hybrid bonding two films of electrodeposited copper.

### DETAILED DESCRIPTION

The present inventors have realized that controlling the growth of the grains of Cu films in Cu to Cu hybrid bonding during semiconductor device manufacturing allows for an improved successful Cu to Cu bond. For example, the bond may be more reliable, durable, strong, and/or have a reduced number of voids. Enabling Cu to Cu bonding may provide a way to have ultra-fine pitch and small contact sizes, which may lead to higher number of electrical connections. However, if the Cu grains grow before the annealing process, the interface between the two Cu surfaces may be poor and may lead to voiding and lower conductivity in the resulting product.

Additionally, the inventors have realized that the properties of the electroplated Cu may play a role in the enabling of Cu to Cu bonding. Preferably, the Cu films resulting from the electroplating process may allow for controlled or engineered grain growth while still maintaining a bottom-up fill characteristic to fill small, high aspect ratio dual damascene structures. Furthermore, the inventors have realized that the amount of incorporated impurities in the Cu deposit may also play a role in the formation of voids after the annealing process. For example, preferably the number of incorporated impurities in the Cu deposit is low.

The methods and compositions described herein may allow for the control of mechanical properties of plated Cu and/or Cu-alloy films. The methods and compositions described herein may allow for the control of the grain structure of the plated Cu and/or Cu-alloy films. For example, the methods and compositions described herein may allow for grain engineering of large grain (e.g., greater than 1 μm) or small grain (e.g., about 1 nm to about 500 nm, or about 5 nm to about 500 nm) Cu and/or Cu-alloy films. The methods and compositions described herein may allow for controlled grain growth in plated Cu films with annealing. The methods and compositions described herein may also allow for the tailoring of annealing temperatures for the deposited Cu films. Instead of, or in addition to, controlling and/or modifying the grain structure of the deposited Cu films, the methods and compositions described herein may also allow for the control of the hardness, resistivity, thermal stability, fill capability, and/or deposit purity of deposited Cu films. The methods and compositions described herein may provide for deposited copper with improved bonding capabilities (e.g., for hybrid and/or direct Cu—Cu bonding) for use in semiconductor device manufacturing.

The methods and compositions described herein may also allow for the control of mechanical properties for copper interconnections in hybrid bonding. The hybrid bonding may be hybrid bonding on a plurality of dies having copper interconnections. The plurality of dies may be attached on wafers and the hybrid bonding may be used for wafer-to-wafer connections. Instead of, or in addition to, wafer-to-wafer connections, the methods and compositions described herein for use with hybrid bonding may also allow for wafer-to-die and/or die-to-die connections. The methods and compositions described herein may allow for hybrid bonding with a controlled grain structure.

While some embodiments of the methods and compositions are directed to applications for Cu to Cu bonding, such as hybrid or direct bonding, other embodiments may be directed to other copper electroplating applications that may be used in integrated circuit and/or semiconductor manufacturing. For example, these applications can include, but are not limited to, wafer level packaging such as redistribution layers, pillars, through silicon via, and/or Damascene plating.

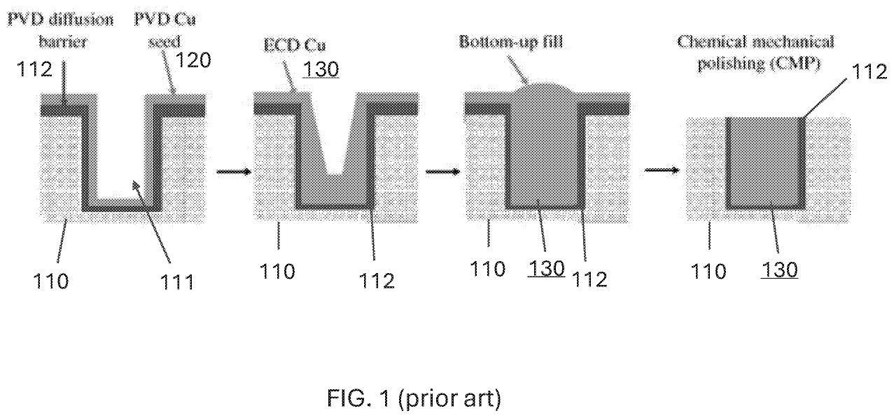

FIG. 1 illustrates the use of copper electrodeposition for the nanofabrication of electronics devices. A substrate 110 (e.g., a printed circuit board (PCB)) may include one or more vias 111 that can be filled by the electrochemical deposition (ECD) of copper. The substrate's surface may be covered, entirely or in part, by a copper layer 120, which may be formed in a variety of manners. For example, the copper layer 120 can be a copper seed layer, which may be deposited using a variety of techniques including those known by one skilled in the art, including, but not limited to, physical vapor deposition (PVD), chemical vapor deposition, or atomic layer deposition. During electrodeposition, the copper layer 120 may act as a cathode to allow copper ions to gain electrons at the surface of the copper layer 120 and aid in the deposition of copper on the substrate 110. The copper layer 120 may vary in thickness depending on the application (e.g., Damascene, through-substrate via (TSV), redistribution layer (RDL)). For example, the copper layer 120 may be about 1 nm to about 500 nm thick. For example, the copper layer 120 may be about 1 nm, about 5 nm, about 10 nm, about 20 nm, about 30 nm, about 40 nm, about 50 nm, about 60 nm, about 70 nm, about 80 nm, about 90 nm, about 100 nm, about 150 nm, about 200 nm, about 250 nm, about 300 nm, about 350 nm, about 400 nm, about 450 nm, or about 500 nm thick, including all values in between.

The substrate 110 may also include a diffusion barrier layer 112 to protect against the interdiffusion of materials. The diffusion barrier layer 112 may also be referred to herein to as a barrier layer. The diffusion barrier layer 112 may include a tantalum and/or tantalum nitride layer. The diffusion barrier layer 112 may be deposited using a variety of techniques including those known by one skilled in the art, including, but not limited to, physical vapor deposition (PVD), chemical vapor deposition, or atomic layer deposition. If a diffusion barrier layer 112 is present, the copper layer 120 may be deposited on top of the diffusion barrier layer 112. The ECD copper (Cu) 130 filling may be a bottom-up fill to allow for a void free filling. Following filling with ECD copper 130, the substrate 110 may be chemically polished to create a flat surface. This process may be utilized for damascene, through silicon via (TSV), and packaging applications, including advanced packaging.

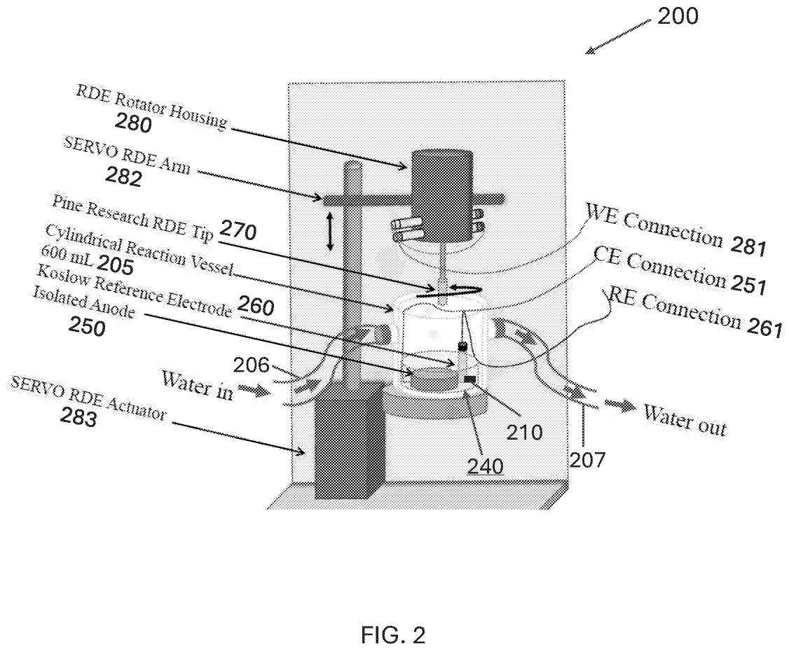

FIG. 2 shows an experimental set up for electroplating copper using an electroplating device 200. The electroplating device 200 may include a reaction vessel 205 to hold a substrate 210 and a plating bath 240 including components (A), (B), (C), (D), and/or (E). The plating bath 240 may include any of the plating baths described herein. The substrate 210 may include, but is not limited to, a PCB, a silicon wafer, an integrated circuit (IC) substrate, a polymer, or any suitable substrate. As described above, the substrate 210 may include one or more vias that can be filled by the electrochemical deposition (ECD) of copper. The substrate 210 may also include a copper layer (e.g., a copper seed layer) and/or a diffusion barrier as described above. The copper layer (e.g., a copper seed layer) may assist in the formation of a uniform, void-free ECD copper layer. The substrate 210 may function as the cathode.

The reaction vessel 205 may also include an anode 250 with a counter electrode (CE) connection 251, a reference electrode 260 with a reference electrode (RE) connection 261, and a rotating disk electrode (RDE) tip 270. The reaction vessel 205 may also include one or more pipes or conduits 206, 207 to supply and/or remove water from the reaction vessel, respectively.

The electroplating device 200 may also include a RDE rotator housing 280 with a working electrode (WE) connection 281 that is attached via an arm 282 to a RDE actuator 283.

### Components of the Electroplating Solution

A composition for an electroplating bath (also referred to herein as the plating bath) may include the following components (A), (B), (C), (D), and/or optionally (E). A substrate (e.g., a printed circuit board, a silicon wafer, an IC substrate, a polymer), which has been made electrically conductive may be plated with copper using the composition described herein.

Component (A) may include a virgin makeup solution (VMS). The VMS may include the following components: Copper (Cu) ions (A-1), sulfuric acid (H₂SO₄) (A-2), and chloride ions (A-3). The copper ions may be in the form of copper sulfate (CuSO₄). The chloride (Cl) ions may be in the form of hydrochloric acid (HCl) or another source of chloride such as a chloride salt.

The concentration of Cu in the VMS may range from about 2 g/L to about 60 g/L. In some instances, the concentration of Cu in the VMS may range from about 10 g/L to about 60 g/L. For example, the concentration of Cu in the VMS may be about 2 g/L, about 3 g/L, about 4 g/L, about 5 g/L, about 6 g/L, about 7 g/L, about 8 g/L, about 9 g/L, about 10 g/L, about 15 g/L, about 20 g/L, about 25 g/L, about 30 g/L, about 35 g/L, about 40 g/L, about 45 g/L, about 50 g/L, about 55 g/L, or about 60 g/L, including all values in between.

The concentration of sulfuric acid in the VMS may range from about 1 g/L to about 300 g/L. In some instances, the concentration of sulfuric acid in the VMS may range from about 10 g/L to about 200 g/L. For example, the concentration of sulfuric acid in the VMS may be about 1 g/L, about 5 g/L, about 8 g/L, about 10 g/L, about 15 g/L, about 20 g/L, about 25 g/L, about 30 g/L, about 35 g/L, about 40 g/L, about 45 g/L, about 50 g/L, about 55 g/L, about 60 g/L, about 70 g/L, about 80 g/L, about 90 g/L, about 100 g/L, about 150 g/L, about 200 g/L, about 250 g/L, or about 300 g/L, including all values in between. For example, the concentration of sulfuric acid in the VMS may be about 5 g/L to about 200 g/L, or about 8 g/L to about 100 g/L, or about 10 g/L to about 80 g/L.

The concentration of Cl ions in the VMS may range from about 10 ppm to about 100 ppm on a weight basis. For example, the concentration of Cl ions in the VMS may be about 10 ppm, about 15 ppm, about 20 ppm, about 25 ppm, about 30 ppm, about 35 ppm, about 40 ppm, about 45 ppm, about 50 ppm, about 55 ppm, about 60 ppm, about 70 ppm, about 80 ppm, about 90 ppm, or about 100 ppm, including all values in between.

For example, in the VMS the concentration of the Cu, sulfuric acid, and Cl may be about 10 g/L Cu, about 10 g/L sulfuric acid, and about 10 ppm Cl. Alternatively, in the VMS the concentration of the Cu, sulfuric acid, and Cl may be about 10 g/L Cu, about 10 g/L sulfuric acid, and about 50 ppm Cl.

In another example, in the VMS the concentration of the Cu, sulfuric acid, and Cl may be about 40 g/L Cu, 10 g/L sulfuric acid, and about 50 ppm Cl. In yet another example, in the VMS the concentration of the Cu, sulfuric acid, and Cl may be about 40 g/L Cu, about 40 g/L sulfuric acid, and about 50 ppm Cl. In yet another example, in the VMS the concentration of the Cu, sulfuric acid, and Cl may be about 60 g/L Cu, about 60 g/L sulfuric acid, and about 50 ppm Cl.

In the examples disclosed herein, the convention X-Y-Z when referring to Component (A) (e.g., the VMS solution) refers to A-1/A-2/A-3. In other words, X represents the amount of Cu in g/L, Y represents the amount of sulfuric acid in g/L, and Z represents the amount of Cl in ppm (on a weight basis) in Component (A) or the VMS solution.

The electroplating solution may also include Component (B), which may also be referred to herein as Additive B or Additive 1. Component (B) may include a suppressor. As used herein a “suppressor” refers to an additive that suppresses the plating rate of a metal (e.g., copper) during electroplating. The suppressor may be slow diffusing and interact with the Cl⁻ ions in the plating bath to adsorb to surface. The suppressor may slow the plating kinetics. Suppressor strength refers to the strength of the binding interaction between the Cu surface and the suppressor molecule. For example, a weak suppressor may exhibit a weak binding interaction between the Cu surface and the suppressor molecule. In contrast, a strong suppressor may exhibit a strong binding interaction between the Cu surface and the suppressor molecule. In some instances, the weak suppressor may exhibit its weak binding interaction by being less polarizable than a strong suppressor, i.e., the weak suppressor may have a weaker binding with a surface relative to a strong suppressor. In some instances, the weak suppressor may be less polarizable than a given molecule. For example, the weak suppressor can be less polarizable than a polyethylene glycol (PEG) molecule (e.g., PEG 10000, PEG 5000, and/or PEG 3350).

The suppressor may include an organic compound. For example, the suppressor may include, but is not limited to, polyethylene glycol, polypropylene glycol, polypropylene glycol copolymers and/or polyethylene glycol copolymers, including ethylene oxide-propylene oxide (“EO/PO”) copolymers and/or butyl alcohol-ethylene oxide-propylene oxide copolymers, a polyethylene glycol glyceryl ether, a polyethylene glycol dialkyl ether, a material exhibiting a structure similar to or identical to TECTRONIC® and/or TECTRONIC® R surfactant available from BASF, or a material exhibiting a structure similar to or identical to PLURONIC® surfactant (e.g., Pluronic L44) available from BASF.

The TETRONIC® and/or TETRONIC® R surfactant may have the following formula (I):

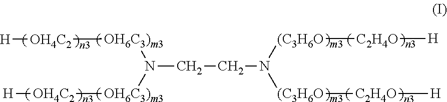

The PLURONIC® surfactant may have the following formula (II):

HO—(C₂H₄O)—ₗ₂(C₃H₆O)—ₘ₂(C₂H₄O)—ₘ₂H (II)

In the examples disclosed herein, one or more of the above compounds may be used as Component (B). For example, Components (B1), (B2), (B3), (B4), (B5), (B6), (B7), and/or (B8) may include any of the above components listed as compounds for Component (B) or other compounds known to those skilled in the art.

The electroplating solution may also include Component (C), which may also be referred to herein as Additive C or Additive 2. Component (C) may include an accelerator. As used herein an “accelerator” refers to an additive that increases the plating rate of a metal (e.g., copper). The accelerator may enable fast diffusion and slow adsorption kinetics. The accelerator may displace the suppressor and accumulate in curved regions of the substrate (e.g., in a fluid via). The accelerator may include an organic compound. For example, the accelerator may include, but is not limited to, 3-mercapto-propylsulfonic acid and its sodium salt, 2-mercapto-ethanesulfonic acid and its sodium salt, and bissulfopropyl disulfide and its sodium salt, 3-(benzthiazoyl-2-thio)-propylsulfonic acid sodium salt, 3-mercaptopropane-1-sulfonic acid sodium salt, ethylenedithiodipropylsulfonic acid sodium salt, bis-(p-sulfophenyl)-disulfide disodium salt, bis-(o-sulfobutyl)-disulfide disodium salt, bis-(o-sulfohydroxypropyl)-disulfide disodium salt, bis-(o-sulfopropyl)-disulfide disodium salt, bis-(o-sulfopropyl)-sulfide disodium salt, methyl-(o-sulfopropyl)-disulfide sodium salt, methyl-(o-sulfopropyl)-trisulfide disodium salt, O-ethyl-dithiocarbonic acid-S-(o-sulfopropyl)-ester, potassium salt thioglycoli acid, thiophosphoric acid-O-ethyl-bis-(o-sulfpropyl)-ester disodium salt, thiophosphoric, acid-tris(o-sulfopropyl)-ester trisodium salt, N,N-dimethyldithiocarbamic acid (3-sulfopropyl) ester, sodium salt, (O-ethyldithiocarbonato)-S-(3-sulfopropyl)-ester, potassium salt, 3-[(amino-iminomethyl)-thio]-1-propanesulfonic acid and 3-(2-benzthiazolylthio)-1-propanesulfonic acid, sodium salt, sodium bis-(3-sodium sulfopropyl) disulfide, bis-(3-sulfopropyl) disulfide, a sulfoalkyl sulfonate, a bis-sulfo compound, and/or a dithiocarbamic acid.

The electroplating solution may also include Component (D), which may also be referred to herein as Additive D or Additive 3. Component (D) may include a bromine solution to provide a concentration of bromine (Br) ions. The bromine ions may be provided by various bromine-containing compounds including, but not limited to, hydrobromic acid and/or a bromine salt including, but not limited to, sodium bromide and/or potassium bromide. In one embodiment, the bromine solution may include the following components: sodium bromide (NaBr) (D-1), sulfuric acid (H₂SO₄) (D-2), and copper sulfate (CuSO₄) (D-3).

In a Component (D) solution, when the bromine ions are provided by a bromine salt, for example, sodium bromide, the concentration of sodium bromide may range from about 0.1 g/L to about 1.5 g/L. For example, the concentration of sodium bromide in the bromine solution may be about 0.1 g/L, about 0.2 g/L, about 0.3 g/L, about 0.4 g/L, about 0.5 g/L, about 0.6 g/L, about 0.7 g/L, about 0.8 g/L, about 0.9 g/L, about 1.0 g/L, about 1.1 g/L, about 1.2 g/L, about 1.3 g/L, about 1.4 g/L, or about 1.5 g/L, including all values in between. Preferably the sodium bromide is about 0.6 g/L to about 1.0 g/L, for example about 0.7 g/L to about 0.9 g/L.

In a Component (D) bromine solution, the concentration of Cu ions may range from about 50 mg/L to about 5 g/L. For example, the concentration of Cu ions in the bromine solution may be about 50 mg/L, about 100 mg/L, about 150 mg/L, about 200 mg/L, about 250 mg/L, about 300 mg/L, about 350 mg/L, about 400 mg/L, about 450 mg/L, about 500 mg/L, about 550 mg/L, about 600 mg/L, about 700 mg/L, about 800 mg/L, about 900 mg/L, about 1 g/L, about 2 g/L, about 3 g/L, about 4 g/L, or about 5 g/L, including all values in between. Preferably the concentration of Cu ions may be about 300 mg/L to about 800 mg/L, for example about 400 mg/L to about 700 mg/L. Preferably the bromine solution has a concentration of Cu ions that is greater than 50 mg/L to reduce biological growth.

In a Component (D) bromine solution, when the Cu ions are provided by copper sulfate, the concentration of copper sulfate (D-3) may range from about 50 mg/L to about 5 g/L. For example, the concentration of copper sulfate (D-3) in the bromine solution may be about 50 mg/L, about 100 mg/L, about 150 mg/L, about 200 mg/L, about 250 mg/L, about 300 mg/L, about 350 mg/L, about 400 mg/L, about 450 mg/L, about 500 mg/L, about 550 mg/L, about 600 mg/L, about 700 mg/L, about 800 mg/L, about 900 mg/L, about 1 g/L, about 2 g/L, about 3 g/L, about 4 g/L, or about 5 g/L, including all values in between. Preferably the concentration of copper sulfate (D-3) may be about 300 mg/L to about 800 mg/L, for example about 400 mg/L to about 700 mg/L. Preferably the bromine solution has a concentration of copper sulfate (D-3) that is greater than 50 mg/L to reduce biological growth.

In a Component (D) bromine solution, the concentration of sulfuric acid (D-2) may range from about 1 g/L to about 10 g/L. For example, the concentration of sulfuric acid may be about 1 g/L, about 2 g/L, about 3 g/L, about 4 g/L, about 5 g/L, about 6 g/L, about 7 g/L, about 8 g/L, about 9 g/L, or about 10 g/L, including all values in between. Preferably the concentration of sulfuric acid may be about 4 g/L to about 6 g/L, for example about 5 g/L.

The sulfuric acid (D-2) may be added to the bromine solution to adjust the pH of the bromine solution. Preferably the bromine solution has a pH of less than or about equal to 2 to reduce biological growth. For example, the bromine solution may have a pH of about 2, about 1.9, about 1.8, about 1.7, about 1.6, about 1.5, about 1.4, about 1.3, about 1.2, about 1.1, or about 1. More preferably the bromine solution has a pH of about 1.7 to about 2, for example about 1.8 or 1.9.

The electroplating solution may also optionally include Component (E), which may also be referred to herein as Additive E. Component E may include a leveler. As used herein a “leveler” refers to an additive that enables a uniform metal deposit. The leveler may slow diffusion and slow adsorption. The leveler may adsorb faster at sites where the roughness is increased (e.g., due in part to accelerator accumulation). The leveler may include, but is not limited to, polyethylenimine, polyamidoamines, polyallylamines, and reaction products of a nitrogen base (e.g., a primary, secondary, tertiary, or quaternary alkyl amine, an aryl amine, a heterocyclic amine, an alkylated aryl, a heterocyclic amines with an epoxide, a dialkylamine, a trialkylamine, an arylalkylamine, a diarylamine, imidazole, triazole, tetrazole, benzimidazole, benzotriazole, piperidine, morpholine, piperazine, pyridine, oxazole, benzoxazole, pyrimidine, quinoline, or isoquinoline) with an epoxide (e.g., an epihalohydrin including epichlorohydrin or epibromohydrin, a monoepoxide compound, a polyepoxide compound), a polyalkyl imine, a salt of 1-hydroxyethyl-2-alkyl imidazoline, an auramine and derivatives thereof, methyl violet and derivatives thereof, crystal violet and derivatives thereof, or Janus black and derivatives thereof.

In one embodiment, Component (D) may be used instead of Component (E). For example, the electroplating solution may include bromine ions (e.g., Component (D-1)) but may not include a leveler (e.g., Component (E)). This may result in fine sized grains in comparison to when Component (E) is used in place of Component (D)—see Conventional Example in Table 2.

In another embodiment, Component (E) may be used in addition to Component (D).

In the examples disclosed herein, the convention P/Q/R mL/L when referring to the components of the plating bath represents the amount of Components (B)/(C)/(D) respectively in the plating bath. In other words, P represents the amount of Component (B) in mL/L, Q represents the amount of Component (C) in mL/L, and R represents the amount of Component (D) in in mL/L in the plating bath.

A plating bath may be prepared using the examples disclosed herein. The plating bath may include at least one of Components (A), (B), (C), (D), and/or E. In operation, Component (A) (e.g., the VMS) is dosed with a certain amount of one or more additives (e.g., Components (B), (C), (D), and/or (E)).

In one embodiment, the plating bath includes Components (A), (B), (C), and (D).

The concentration of bromine ions (e.g., Component (D-1)) in the plating bath may be about 5 ppm to about 200 ppm, for example about 10 ppm to about 100 ppm or about 20 ppm to about 70 ppm. The concentration of component (C) in the plating bath may be about 5 ppm to about 100 ppm, for example about 10 ppm to about 60 ppm, or about 20 ppm. The concentration of Component (B) in the plating bath may be about 5 mL/L to about 20 mL/L.

In another embodiment, the plating bath includes Components (A), (B), (C), (D), and (E). The concentration of bromine ions (e.g., Component (D-1)) in the plating bath may be about 5 ppm to about 200 ppm, for example about 10 ppm to about 100 ppm or about 20 ppm to about 70 ppm. The concentration of component (C) in the plating bath may be about 10 ppm to about 60 ppm, for example about 20 ppm. The concentration of Component (B) in the plating bath may be about 5 mL/L to about 20 mL/L. The concentration of Component (E) in the plating bath may be about 5 mL/L to about 30 mL/L.

In operation, a substrate (e.g., a printed circuit board, a silicon wafer, an IC substrate, a polymer) can be electroplated with copper by contacting the substrate with a plating bath including Components (A), (B), (C), (D), and/or E. Prior to electroplating, the substrate may be made electrically conductive, e.g., by electrifying a copper seed layer on the substrate. A current density may be applied to the substrate, for example, using the electroplating device shown in FIG. 2. The electroplating is performed for a period of time to deposit a metal (e.g. copper) having a desired thickness and morphology on the substrate. The current density may range from about 3 mA/cm² to about 90 mA/cm². For example, the applied current density may be about 3 mA/cm², about 5 mA/cm², about 10 mA/cm², about 15 mA/cm², about 20 mA/cm², about 25 mA/cm², about 30 mA/cm², about 35 mA/cm², about 40 mA/cm², about 45 mA/cm², about 50 mA/cm², about 55 mA/cm², about 60 mA/cm², about 65 mA/cm², about 70 mA/cm², about 75 mA/cm², about 80 mA/cm², about 85 mA/cm², or about 90 mA/cm², including all values in between. The period of time may be about 0.5 minutes to about 2 hours. In some instances, the period of time may be about 5 minutes to about 2 hours, for example between about 30 minutes and about 90 minutes, or at least one hour.

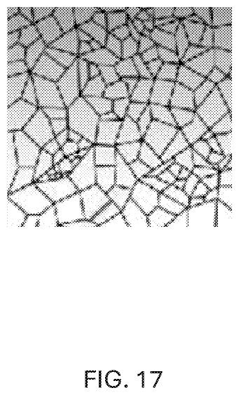

The applied current density may affect the resulting grain stability and/or the filling performance. The applied current density may affect the thermal grain stability. Without being bound to a particular theory, changing the applied current density may change the inhibition density, which may change how the copper is deposited during electroplating (e.g., how the copper is nucleated and grown during electroplating). Cu (metal) grains may form/deposit in a certain way depending on the plating chemistry and plating conditions (e.g., current density, pulse (on-off current), and agitation. For example, fine grain Cu may be a condition of unoriented dispersion (UD) which is shown in FIG. 17. UD may imply that there is no preferred crystal orientation. Changing the J_{avg}/CMₑ^{Z+}(Current density/Cu ion concentration) and inhibition intensity (which may be modified based on Components (B), (C), (D), and/or (E)). Certain additives may adhere to the preferred phase (e.g., higher inhibition). In contrast, certain additives may provide more Cu ions on the deposition surface (e.g., lower inhibition).

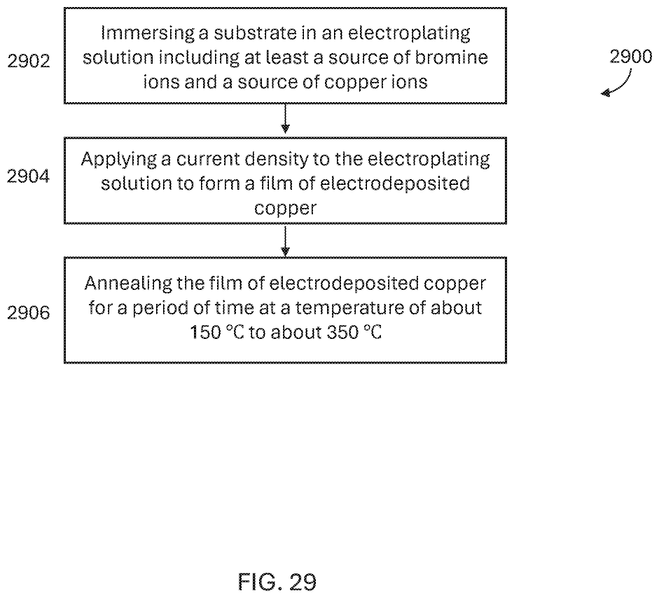

FIG. 29 shows an example method 2900 for making a film of electrodeposited copper according to the inventive concepts and compositions disclosed herein. The method begins at step 2902 by immersing a substrate in an electroplating solution. The substrate may be any of the substrates disclosed herein, for example, the substrate may include, but is not limited to, a printed circuit board, a silicon wafer, an IC substrate, or a polymer. The electroplating solution may include any of the electroplating solutions described herein. Preferably the electroplating solution includes at least a source of bromine ions and a source of copper ions. Thereafter, at step 2904, a current density is applied to the electroplating solution to form a first film of electrodeposited copper on the first substrate. As described herein, the current density may range from about 3 mA/cm² to about 90 mA/cm². The current density may be applied for a period of time that may range from about 0.5 minutes to about 2 hours. The resulting film of electrodeposited copper may be a copper metal pad. Then, at step 2906, the resulting film of electrodeposited copper may be annealed for a period of time at a temperature of about 150 °C to about 350 °C. The period of time may be about 5 minutes to about 2 hours.

The electroplating solutions disclosed herein may be used for the electrodeposition of copper in planar configurations, pads, and/or trench filling (e.g., to fill a via). The electroplating solutions disclosed herein may also be used to cap off a trench or via (e.g., following electroplating in another electroplating solution first to fill a trench and then capping of the trench by electroplating with the solutions disclosed herein second). Table 1 provides examples of different electroplating solutions, current densities, and the resulting composition of the electrodeposited copper. The amounts of Components (B), (C), and (D) in Table 1 are for solutions (e.g., a kit) of Components (B), (C), and (D) that may be provided to be combined with Component (A) to form an electroplating solution (e.g., a plating bath).

TABLE 1
Different Electroplating Solutions, Current Densities, and Composition of the Electroplated Copper

| | | | Compo- | Compo- | Compo- | | | | | | | | |
|---|---|---|---|---|---|---|---|---|---|---|---|---|---|
| Component (A) VMS | | | nent | nent | nent | Current | Composition of Electroplated Copper | | | | | | |
| Cu | H₂SO₄ | Cl | B Solution | C Solution | D Solution | Density | Cl | S | O | C | Br | N | Total |
| (g/L) | (g/L) | (ppm) | (mL/L) | (mL/L) | (mL/L) | (mA/cm²) | (ppm) | (ppm) | (ppm) | (ppm) | (ppm) | (ppm) | (ppm) |
| 10 | 10 | 50 | 10 | 1 | 6.5 | 10 | 4.89 | 2.64 | 17.32 | 19.90 | 90.27 | 1.32 | 136.33 |
| 10 | 10 | 50 | 10 | 1 | 6.5 | 30 | 16.95 | 7.23 | 39.06 | 49.76 | 208.29 | 2.77 | 324.07 |
| 40 | 10 | 50 | 10 | 1 | 6.5 | 5.7 | 5.87 | 5.24 | 17.84 | 24.22 | 98.44 | 1.45 | 153.05 |
| 40 | 10 | 50 | 10 | 1 | 6.5 | 8.5 | 7.41 | 10.25 | 26.40 | 47.08 | 143.26 | 2.54 | 236.95 |
| 40 | 10 | 50 | 10 | 1 | 6.5 | 14.2 | 8.65 | 12.63 | 27.16 | 58.83 | 170.48 | 3.05 | 280.79 |
| 40 | 40 | 50 | 5.8 | 1 | 9.8 | 25 | 4.83 | 3.53 | 29.43 | 31.68 | 108.20 | 1.33 | 179.01 |
| 40 | 40 | 50 | 5.8 | 1 | 9.8 | 36 | 8.31 | 5.23 | 46.96 | 48.94 | 165.47 | 2.05 | 276.95 |
| 40 | 40 | 50 | 5.8 | 1 | 9.8 | 46.5 | 10.39 | 6.50 | 56.10 | 63.59 | 186.71 | 2.35 | 325.66 |

The film of electrodeposited copper may have a concentration of bromine (Br) ions in the range of about 0.2 ppm to about 250 ppm. For example, the film of electrodeposited copper may have a concentration of bromine (Br) ions of about 0.2 ppm, about 0.5 ppm. about 1 ppm, about 5 ppm, about 10 ppm, about 15 ppm, about 20 ppm, about 25 ppm, about 30 ppm, about 35 ppm, about 40 ppm, about 45 ppm, about 50 ppm, about 55 ppm, about 60 ppm, about 65 ppm, about 70 ppm, about 75 ppm, about 80 ppm, about 85 ppm, about 90 ppm, about 95 ppm, about 100 ppm, about 150 ppm, about 200 ppm, or about 250 ppm, including all values in between.

Any two or more of the components (A), (B), (C), (D), and/or (E) may be supplied as part of a kit that includes individual bottles containing solutions of the two or more components (A), (B), (C), (D), and/or (E), respectively, and instructions for using at least the two or more components (A), (B), (C), (D), and/or (E) to form an electroplating bath. In one embodiment, component (A) may be sold separately, and the kit may include only components (B), (C), (D), and/or (E). In another embodiment, the component (D) may be sold separately, and the kit may include two or more of components (A), (B), (C), and/or (E). In another embodiment, the kit may include all of components (A), (B), (C), (D), and (E). In yet another embodiment, the kit may include two or more components selected from the group of components of (B), (C), and (D). In yet another embodiment, the kit can include individual bottles containing a solution of two or more of Components (A), (B), (C), (D), and/or (E) that have been combined into a single solution. For example, the kit may include an individual bottle containing a combined solution of Component (A) and (B), a combined solution of Component (A) and (C), a combined solution of Component (A) and (D), and/or a combined solution of Component (A) and (E). In yet another embodiment, the kit can include individual bottles containing a solution of three or more of Components (A), (B), (C), (D), and/or (E) that have been combined into a single solution. For example, the kit may include an individual bottle containing a combined solution of Component (A), (B), and (D) and/or a combined solution of Component (A), (C), and (D).

### Grain Engineered Copper

In electrodeposited metallic films, a grain (also known as a crystallite) refers to a small, individual crystal within the film's structure. Grains are separated by interfaces called grain boundaries, where different crystallographic orientations meet. The arrangement and characteristics of grains, including their size, shape, and orientation, may be collectively referred to as the microstructure of the film. These grains are the fundamental building blocks of the film and are characterized by their size, shape, and orientation. The collective arrangement of these grains determines the overall microstructure of the film, which in turn influences its physical properties, including, but not limited to, its hardness, strength, ductility, and/or toughness. For example, fine-grained films may be harder, stronger, and/or smoother while columnar-grained films may be more ductile. During electrodeposition, the grain structure may be influenced by factors including but not limited to the plating bath composition, current density, temperature, and/or the substrate material.

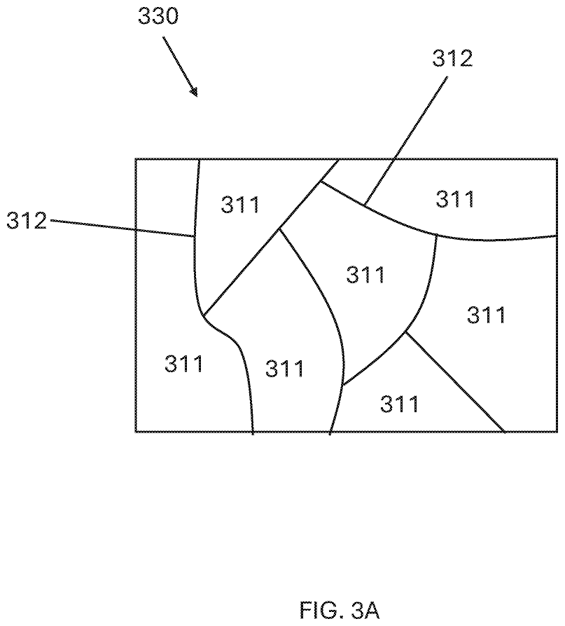

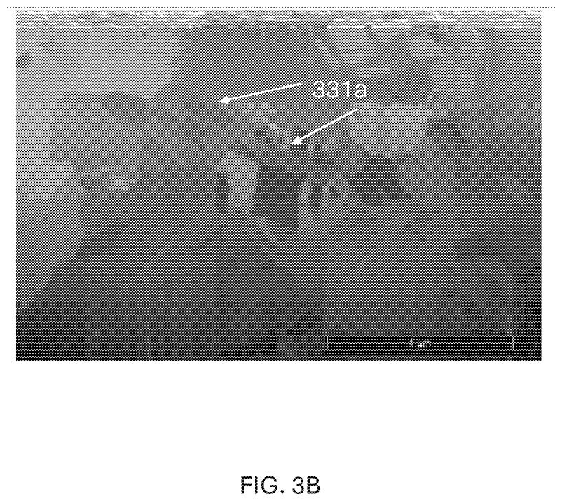

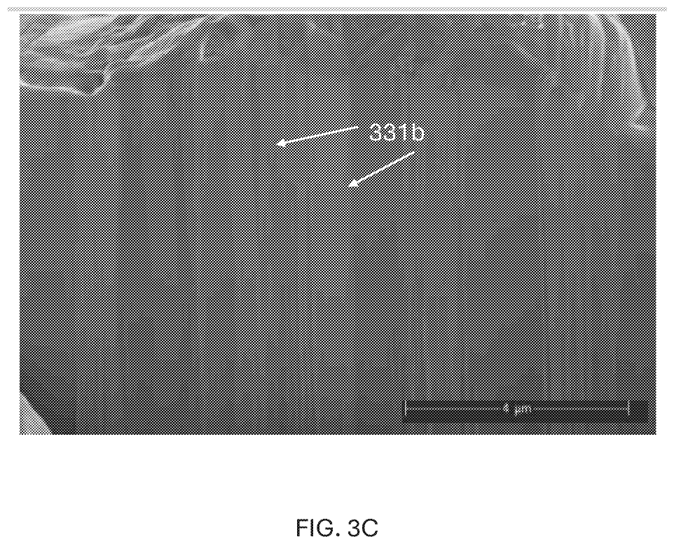

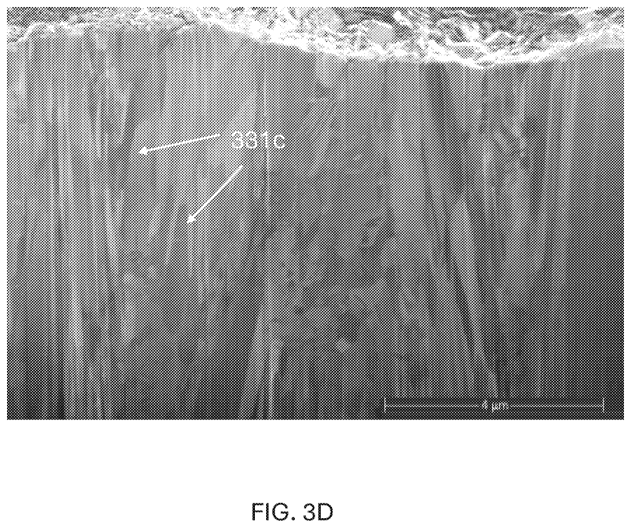

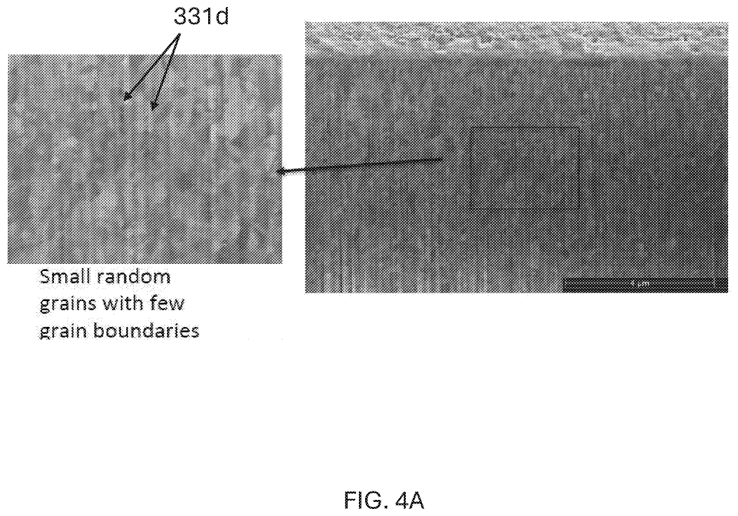

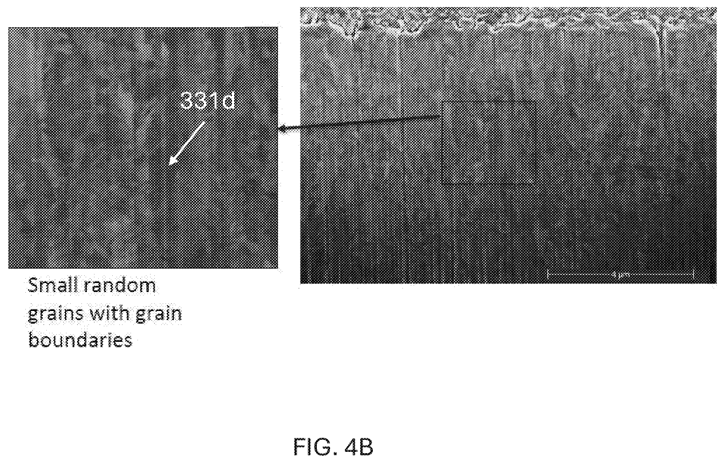

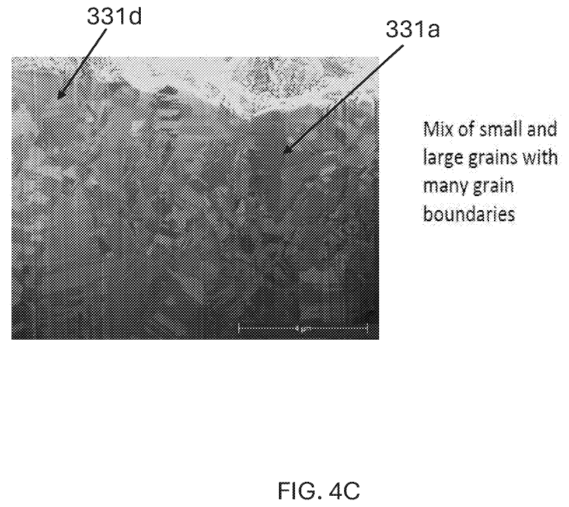

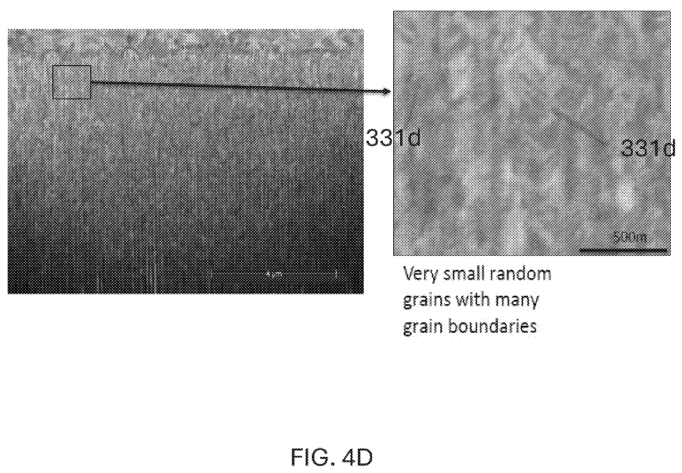

FIG. 3A shows an example schematic of an electrodeposited metallic film 330 with a plurality of grains 311 separated by grain boundaries 312. FIGS. 3B-3D and 4A-4D show images of example grain structures of plated Cu films. As shown in FIGS. 3B-3D the plated Cu films may have large grains 331a (FIG. 3B), oriented random large grains 331c (FIG. 3D), and/or columnar grains 331b (FIG. 3C). As shown in FIGS. 4A-4D, the plated Cu films may also have small grains 331d.

The electroplating solutions disclosed herein may be used to obtain grain engineered copper. As disclosed herein “grain engineered copper” refers to controlling the morphology and/or grain structure of the deposited Cu film through the electroplating solution, applied current density, and/or annealing temperature. The grain engineered copper may be obtained using a variety of concentrations of components (A-1), (A-2), and (A-3) as described above. Preferably, component (B) includes a weak suppressor (e.g., a type of PLURONIC® surfactant). Preferably, the concentration of component (C) in the plating bath ranges from about 5 ppm to about 100 ppm, for example about 10 ppm to about 60 ppm, or about 20 ppm. The concentration of component (C) in the plating bath may be adjusted based on the desired grain size stability. Preferably the concentration of component (D) in the plating bath ranges from about 5 ppm to about 200 ppm, for example, about 10 ppm to about 100 ppm or about 20 ppm to about 70 ppm. The grain engineered copper may be obtained using any of the current densities disclosed herein.

The grain engineered copper may exhibit good grain thermal stability at a range of temperatures and for a period of time. For example, the grain size may remain the same or substantially the same (e.g., less than 50 nm difference) for at least a month at room temperature. The grain size may also remain the same or substantially the same (e.g., less than 50 nm difference) for several hours (e.g., at least two hours) at temperatures of about 150 °C to about 200 °C. Furthermore, at high temperatures (e.g., about 300 °C to about 350 °C), the grain size may remain the same for several minutes (e.g., five minutes or less).

In one embodiment, following plating in the plating bath, the deposited grain engineered copper may be fine grain. The fine grain copper (also referend to herein as “FG-Cu” or “fine grain copper”) may have a grain size as small as about 1 nm or about 2 nm to about 500 nm. In some instances, the fine grain copper may have a grain size of about 5 nm to about 500 nm. For example, the FG-Cu may have a grain size of about 5 nm, about 10 nm, about 20 nm, about 30 nm, about 40 nm, about 50 nm, about 60 nm, about 70 nm, about 80 nm, about 90 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, or about 900 nm, including all values in between. Preferably, the grain size of the electroplated grain engineered copper may be about 10 nm to about 150 nm, for example about 30 nm to about 120 nm, including all values in between.

Following plating in the plating bath, the average grain size of the electroplated grain engineered fine grain copper may range from about 30 nm to about 100 nm. For example, the grain engineered copper may have an average grain size of about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, or about 100 nm, including all values in between.

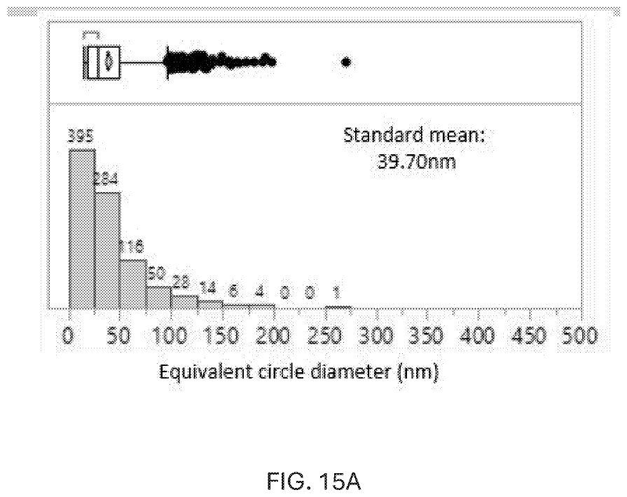

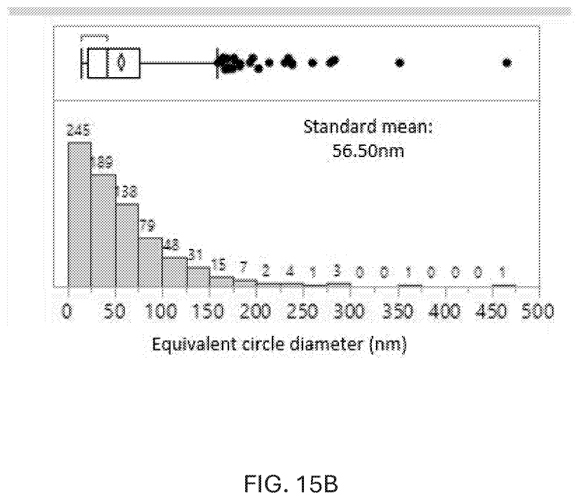

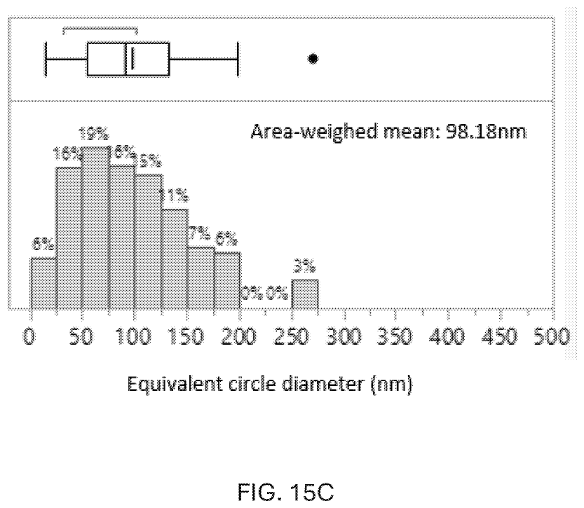

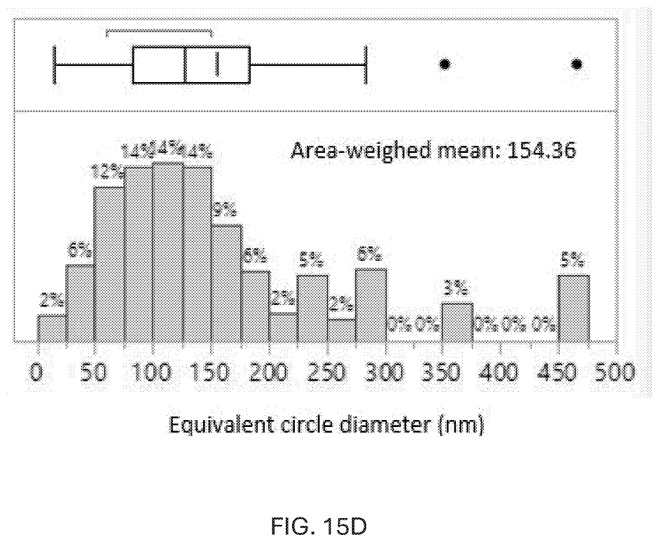

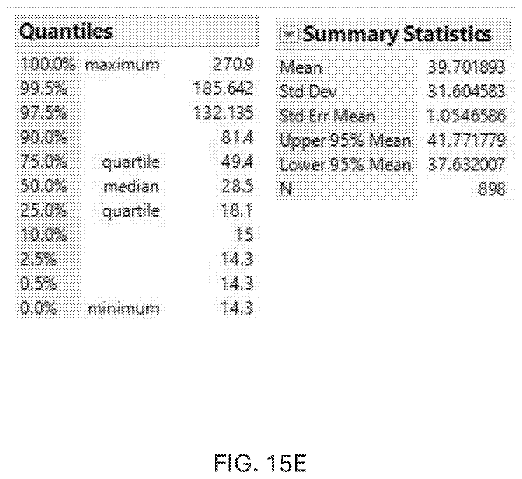

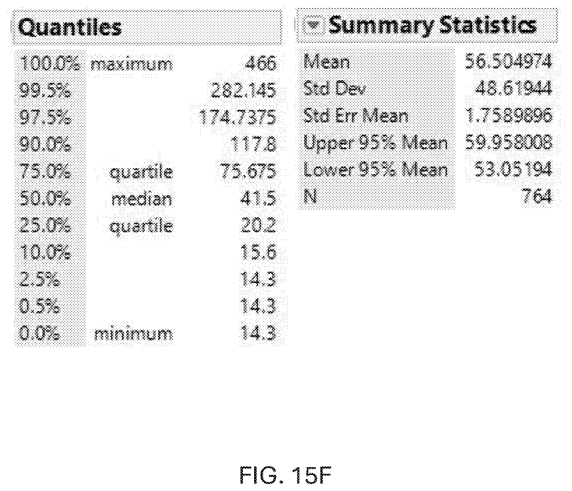

FIGS. 15A-15F illustrate the grain size distribution of electroplated grain engineered fine grain copper. Most of the grains in the electroplated grain engineered fine grain copper were smaller than 150 nm, for example less than 130 nm. Some of the grains in the electroplated grain engineered fine grain copper were less than 50 nm, for example less than 30 nm.

FIGS. 4A-4D illustrate images of grain engineered fine grain copper. As shown in FIGS. 4A-4D, the fine grain copper may have small random grains with grain boundaries (FIG. 4A), small random grains with grain boundaries (FIG. 4B), very small random grains with grain boundaries (FIG. 4D), and/or a mix of small and large grains with many grain boundaries (FIG. 4C).

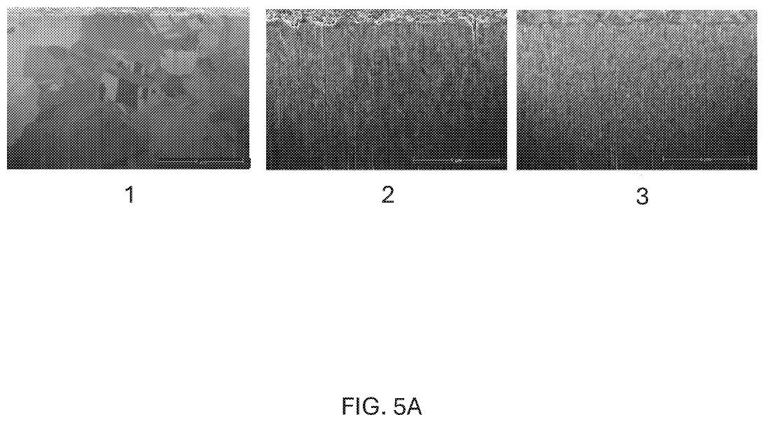

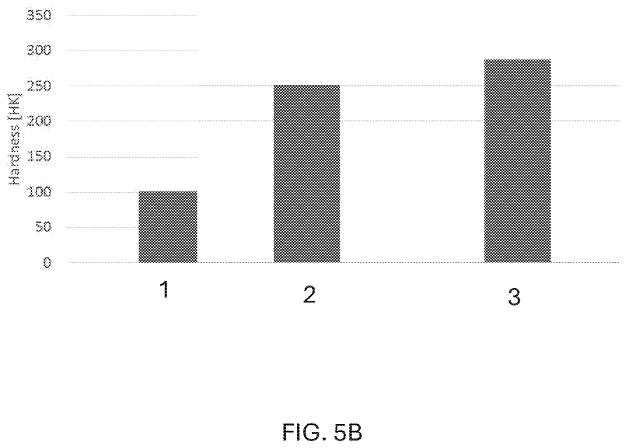

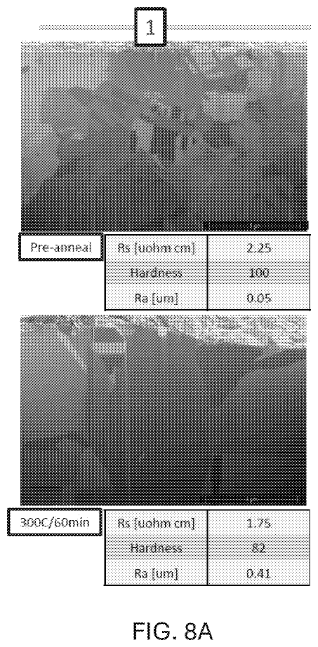

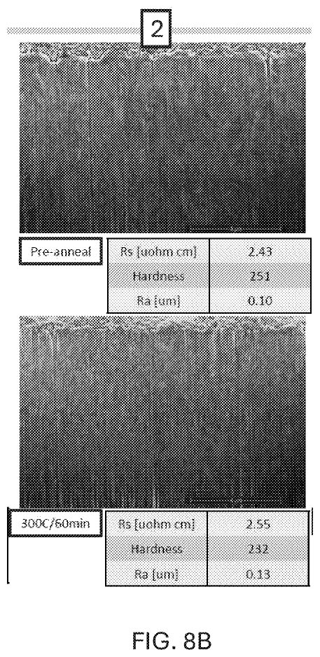

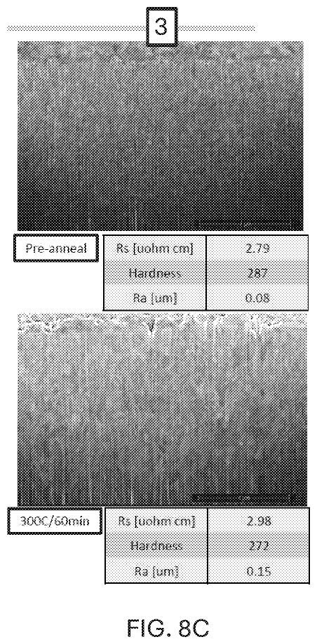

FIG. 5A shows scanning electron microscopy images of focused ion beam polished samples for a large grain plated Cu film (left, #1) and small grain plated Cu films (middle, #2, and right, #3). FIG. 5B is a graph showing the correlation between hardness and grain structure for the samples 1-3 shown in FIG. 5A. As shown in FIGS. 5A and 5B, large grain copper (left panel #1) may be less hard than fine grain copper (middle #2 and right #3 panels). Thus, the deposited grain engineered copper films disclosed herein may have increased hardness. FIGS. 8A-8C shows images of example grain structures of plated Cu films (large grain #1 (FIG. 8A), fine grain #2 (FIG. 8B), and fine grain #3 (FIG. 8C)) and their hardness values before (top images) and after annealing (bottom images).

In one embodiment, the grain engineered copper may exhibit a growth in grain size following annealing (or bonding) at temperatures from about 150 °C to about 350 °C. For example, the annealing temperature may be about 150 °C, about 200 °C, about 250 °C, about 300 °C, or about 350 °C, including all values in between. The grain engineered copper may be tailored to anneal at a specific temperature as a result of the chemistry of the plating bath and/or the applied current density during plating.

The change (e.g., growth) in grain size of the grain engineered copper following annealing may range from about 5 nm to about 100 μm. For example, following annealing, the grain size of the grain engineered copper may increase by about 5 nm, about 10 nm, about 15 nm, about 20 nm, about 25 nm, 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 950 nm, about 1 μm, about 5 μm, about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm, or about 100 μm, including all values in between.

In one embodiment, the grain engineered copper may be fine grain (e.g., about 1 nm to about 500 nm, or about 5 nm to about 500 nm) after plating and then following annealing, the grain engineered copper may grow to large grain (e.g., greater than 1 μm). For example, upon annealing, the grains may grow from an initial size (e.g., fine grain) to a larger size (e.g., large grain or such as about the size of a via or trench width). In this embodiment, the grain engineered copper may be referred to herein as “meta-stable FG-Cu,” “meta-stable fine grain engineered copper,” “thermal dynamic copper,” or “TD-Cu.” In this embodiment, following annealing, the meta-stable FG-Cu may have a second grain size of about 1 μm to about 200 μm. For example, the following annealing the deposited grain engineered copper may have a grain size of about 1 μm, about 5 μm, about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm, about 100 μm, about 150 μm, or about 200 μm, including all values in between.

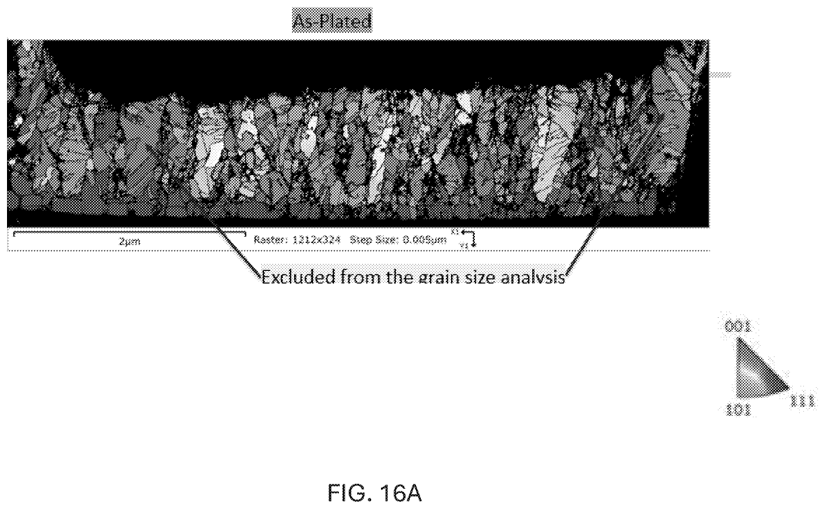

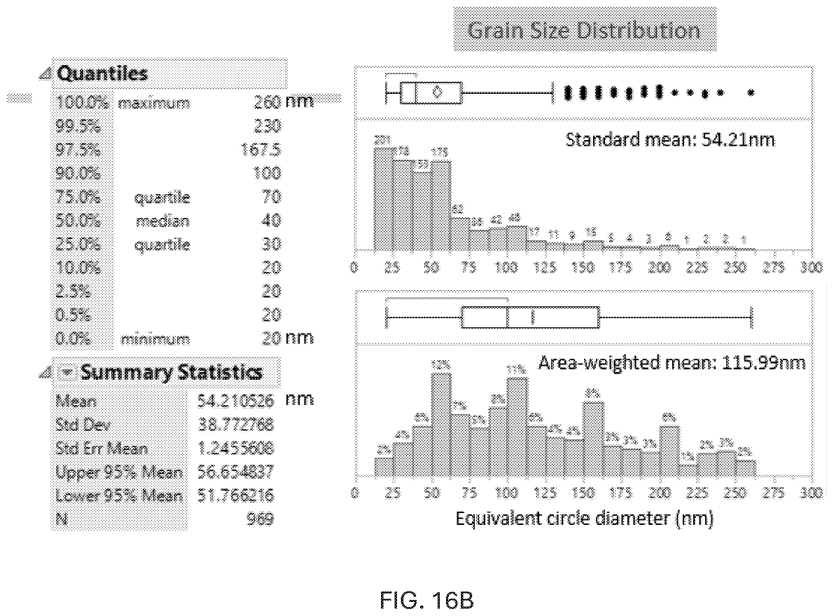

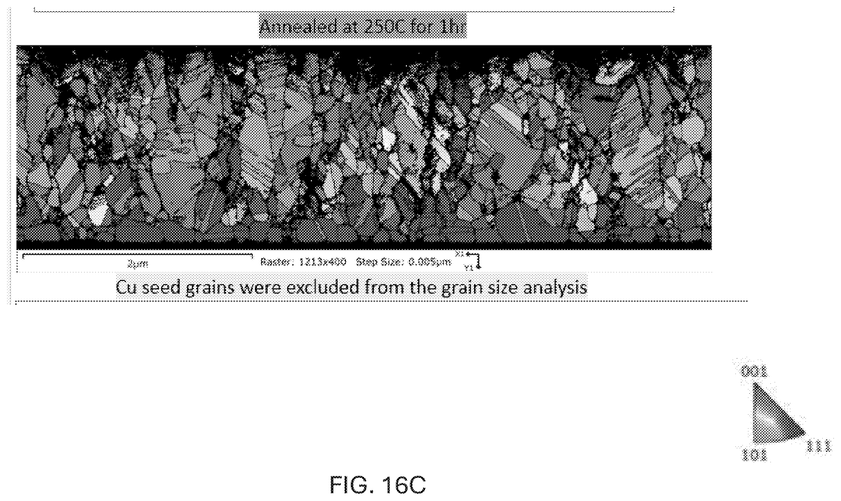

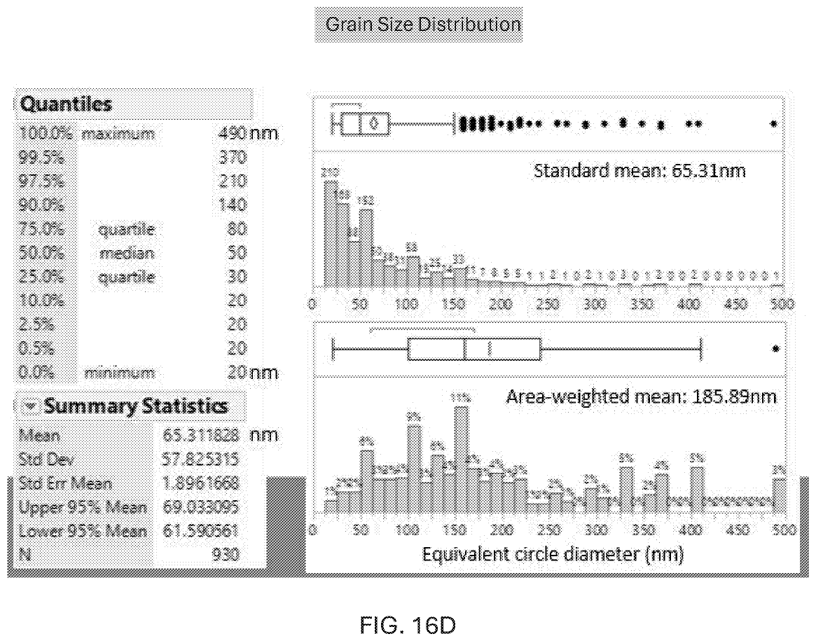

FIGS. 16A-16D illustrate the grain size distribution of electroplated grain engineered stable fine grain copper following annealing at 250 °C for one hour. In one embodiment, following annealing, the grain engineered fine grain copper may increase in size by about 5 nm to about 20 nm, for example about 10 nm to about 15 nm. Following annealing, the area weighted grain size may increase by about 40 nm to about 90 nm, for example about 50 nm to about 70 nm. Following annealing, the grain engineered fine grain copper may still exhibit a high hardness, similar to the hardness of the grain engineered fine grain copper prior to annealing.

In another embodiment, the grain engineered copper may be fine grain after plating and remain fine grain following annealing. In this embodiment, the grain engineered copper may be referred to herein as “stable FG-Cu” or “stable fine grain engineered copper.” In this embodiment, the grain size of the grain engineered copper following annealing may still increase in size. However, the grain size of the stable FG-Cu following annealing may still be fine grain (e.g., about 1 nm to about 500 nm, or about 5 nm to about 500 nm). For example, following annealing, the deposited grain engineered copper may have a second grain size that is similar to the first grain size. For example, following annealing the deposited grain engineered copper may have a grain size of about 5 nm, about 10 nm, about 20 nm, about 30 nm, about 40 nm, about 50 nm, about 60 nm, about 70 nm, about 80 nm, about 90 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, or about 900 nm, including all values in between.

In yet another embodiment, following annealing at a higher temperature (e.g., 300 °C or 350 °C), the grains of the stable FG-Cu may grow to large grain (e.g., greater than 1 μm). For example, following annealing at a higher temperature, the grain size of the stable FG-Cu may increase by about 5 nm, about 10 nm, about 15 nm, about 20 nm, about 25 nm, 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 950 nm, about 1 μm, about 5 μm, about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm, or about 100 μm, including all values in between.

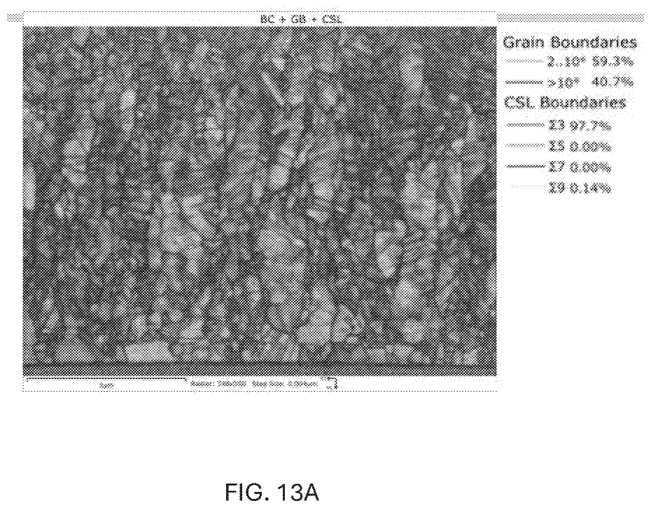

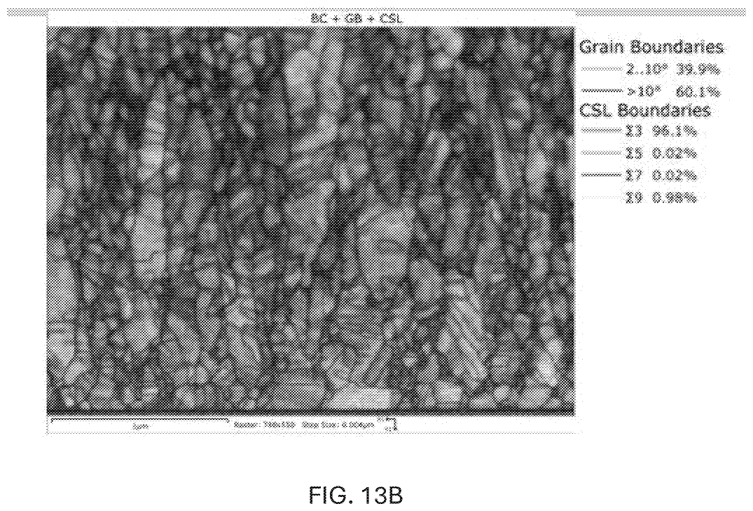

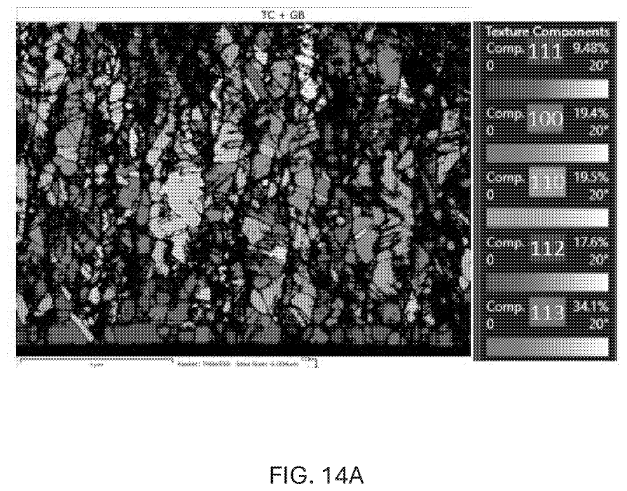

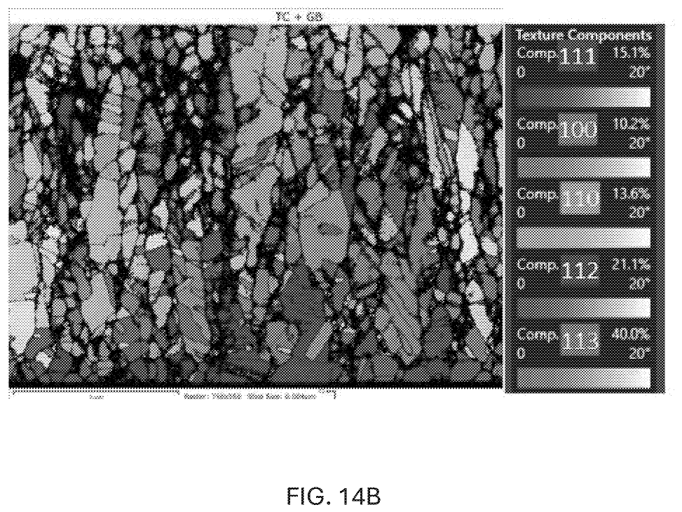

FIGS. 13A-13B show images of the grain boundaries of stable fine grain engineered copper (FIG. 13A) and meta-stable fine grain engineered copper (FIG. 13B) taken by electron BackScatter Diffraction (specifically, Transmission Kikuchi Diffraction (TKD). FIGS. 14A-14B show two-dimensional orientation maps taken by TKD of the grain boundaries of stable fine grain engineered copper (FIG. 14A) and meta-stable fine grain engineered copper (FIG. 14B).

The stable FG-Cu may have less grain boundaries compared to the meta-stable FG-Cu. Both the stable FG-Cu and the meta-stable FG-Cu may exhibit less crystal plane (111) orientation. In such instances, this orientation (e.g., less crystal plane (111) orientation) may be associated with a BackScatter Diffraction or a transmission kikuchi diffraction (TKD) measurement. These factors may contribute to the thermal grain stability of the stable FG-Cu and the meta-stable FG-Cu.

In yet another embodiment, the electroplating solutions disclosed herein may be used to deposit grain engineered copper that anneals at a specific temperature. For example, upon annealing, the grains may grow from an initial size to a larger size, such as about the size of a via or trench width, within a time shorter than two hours after the anneal temperature is applied (e.g., within a time of 5 minutes to 2 hours). In one embodiment, the grain engineered copper may anneal at a lower temperature (e.g., less than 250 °C, such as 200 °C). In another embodiment, the grain engineered copper may anneal at a higher temperature (e.g., about 200 °C to about 350 °C).

Table 2 provides example process conditions and properties for deposited grain engineered copper compared to conventional copper. The concentrations of Components (A), (B), (C), (D), and (E) listed in Table 2 correspond to the final concentration of Components (A), (B), (C), (D), and (E), respectively, in the electroplating solution (e.g., plating bath).

TABLE 2
Example Process conditions and Properties for Grain Engineered Copper.

| | | | | | | | | | | Grain | | |
|---|---|---|---|---|---|---|---|---|---|---|---|---|
| | | | | | | | | | | size | | |
| | Electroplating Solution | | | | | | | | | after | Purity | |
| | Component A | | | Compo- | Compo- | Compo- | Compo- | | Grain | annealing | ppm | |
| | | Sulfuric | | nent | nent | nent | nent | Current | size | 200-250 | (C + N + | Hard- |
| | Cu²⁺ | Acid | HCl | B | C | D | E | Density | after | C/1 hr | S + | ness |
| Example | (g/L) | (g/L) | (mg/L) | (mg/L) | (mg/L) | (mg/L) | (mg/L)) | (mA/cm²) | plating | anneal | Cl + O) | HV |
| 1 | 40 | 10 | 50 | 300 | 20 | 45 | N/A | 2.8 | Fine | Large | 3 | |
| 2 | 40 | 10 | 50 | 300 | 20 | 45 | N/A | 5.6 | Fine | Large | 11 | |
| 3 | 40 | 10 | 50 | 300 | 20 | 45 | N/A | 16.8 | Fine | Fine | 27 | |
| 4 | 40 | 10 | 50 | 300 | 20 | 35 | N/A | 30 | Fine | Fine | 64 | 185 |
| 5 | 40 | 10 | 50 | 300 | 20 | 35 | N/A | 45 | Fine | Fine | 135 | 199 |
| 6 | 40 | 10 | 50 | 200 | 20 | 5 | N/A | 12 | Large | Large | | |
| 7 | 40 | 10 | 50 | 200 | 20 | 5 | N/A | 45 | Fine | Large | | |
| 8 | 40 | 10 | 50 | 200 | 20 | 20 | N/A | 45 | Fine | Fine | | |
| 9 | 40 | 10 | 50 | 200 | 20 | 20 | N/A | 60 | Fine | Fine | | |
| Conven- | 40 | 10 | 50 | 200 | 60 | N/A | 20 | Waveform | Large | Large | 5 | 100 |
| tional | | | | | | | | 10 + 45 | | | | |

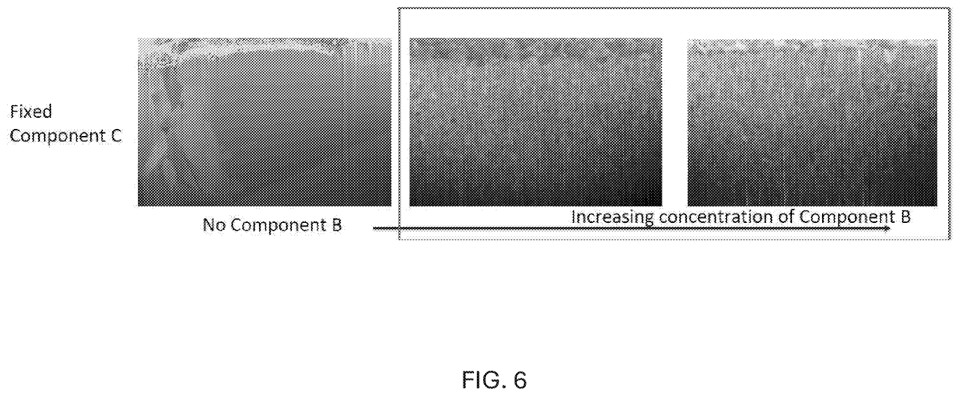

The grain size and average grain size of the deposited grain engineered copper following electroplating may vary depending on the chemistry of the plating bath and/or the applied current density. FIG. 6 shows images of example grain structures of plated Cu films with varying amounts of Component (B) and constant amounts of Components (C) and (D) demonstrating how the chemistry of the plating bath may affect the grain size of the deposited copper. The grain engineered fine grain copper shown inside the box may exhibit hardness values of about 2 to 2.5× that of conventional deposited copper. The grain engineered fine grain copper shown inside the box may also exhibit high thermal stability compared to that of conventional deposited copper.

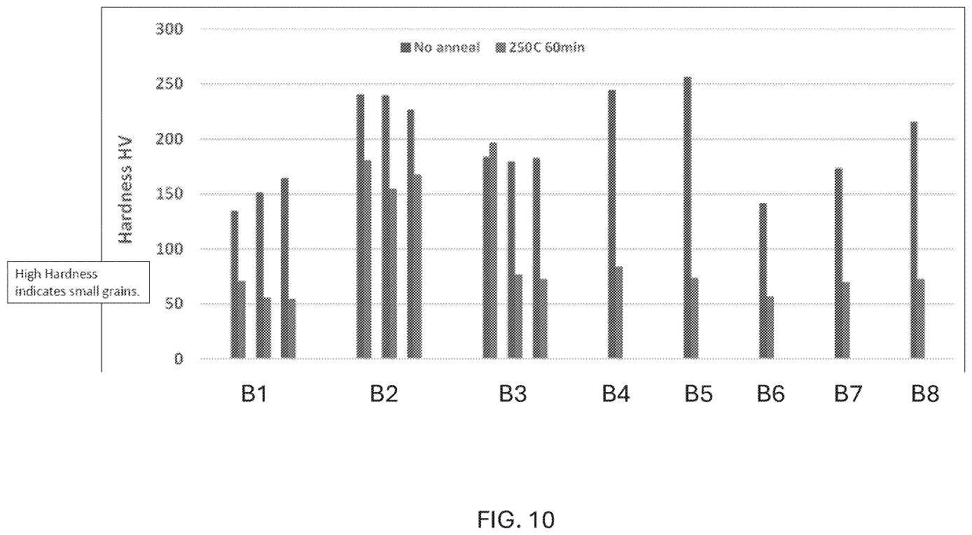

FIG. 10 shows a comparison of Vickers hardness (HV) without annealing (left bars) and following annealing at 250 °C for 60 minutes (right bars) using different electroplating solutions with compounds for Component (B) (e.g., Components B1-B8). As shown in FIG. 10, the hardness of the grain engineered copper films may decrease following annealing, suggesting an increase in grain size. In contrast, prior to annealing the grain engineered copper films may exhibit high hardness values, suggesting a small grain morphology.

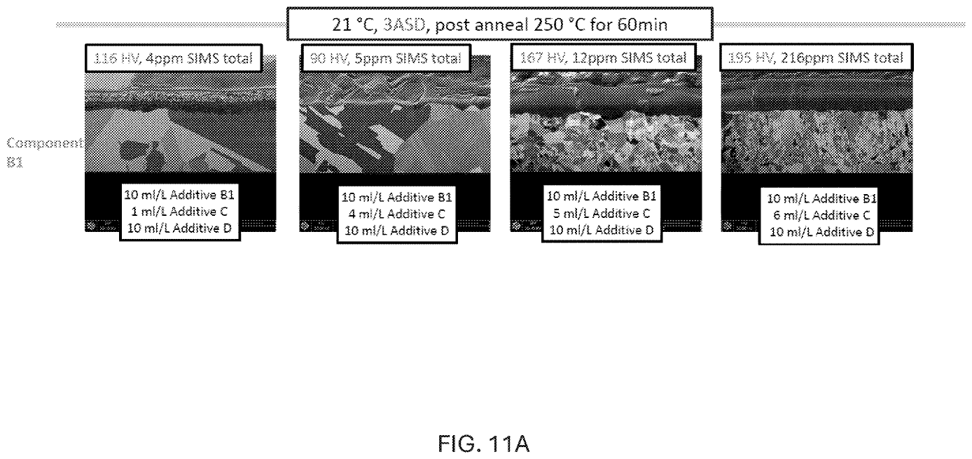

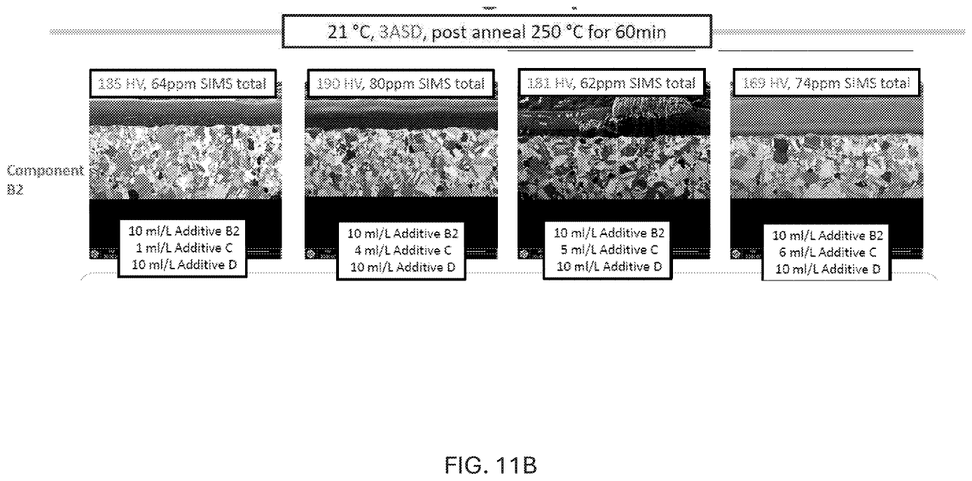

FIGS. 11A and 11B show images of example grain structures of plated Cu films with increasing concentration of Component (C), with two different Component (B), Components (B1) (FIG. 11A) and (B2) (FIG. 11B), and with constant Component (D). The tests were performed at 3 amperes per square decimeter (ASD) with an anneal temperature of 250 °C. As shown in FIGS. 11A and 111B, Component (B) may interact with Component (C), and the selection of Component (B) may impact how sensitive Component (B) is to Component (C). Additionally, the interactions between Components (B), (C), and/or (D) may also affect the grain size and hardness values of the resulting electrodeposited copper film.

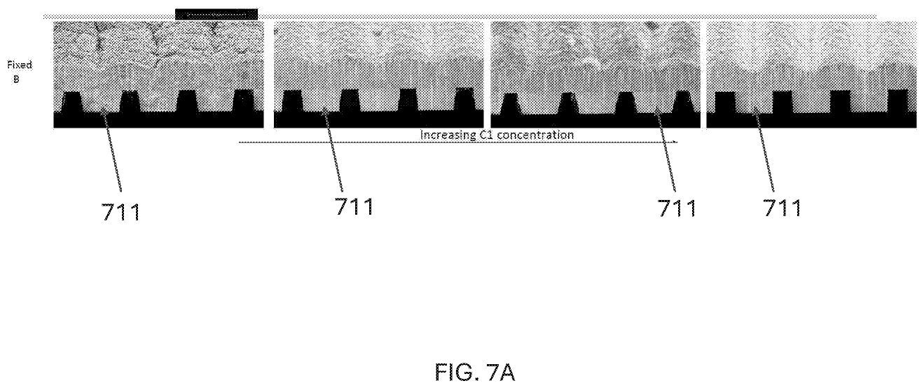

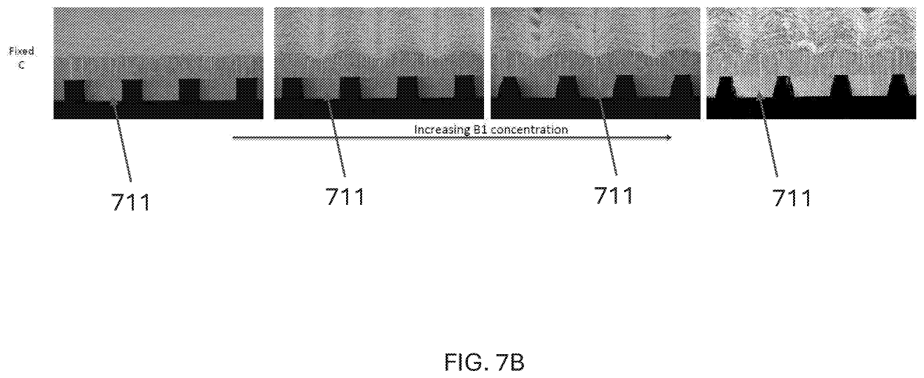

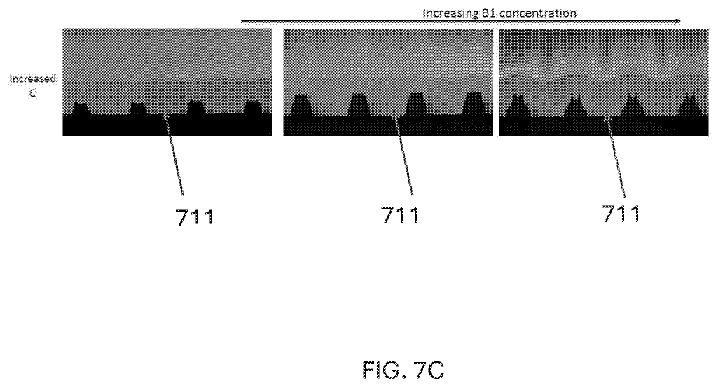

The grain engineered copper may also exhibit a good bottom-up fill and may be void free or substantially void-free. FIGS. 7A-7C shows images of fill behavior for plated Cu films in a 5×5 μm trench or via 711 for varying concentrations of Components (B) and (C) with a fixed amount of Component (D). As shown in FIG. 7A-7C, filling was observed at low concentrations of Component (B) and high concentrations of Component (C) (see FIG. 7C). These conditions also exhibit increased hardness.

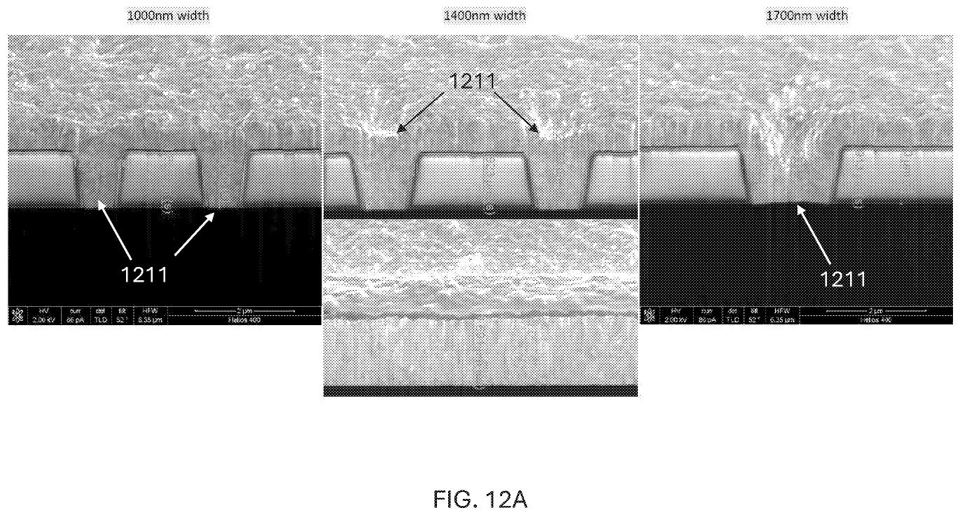

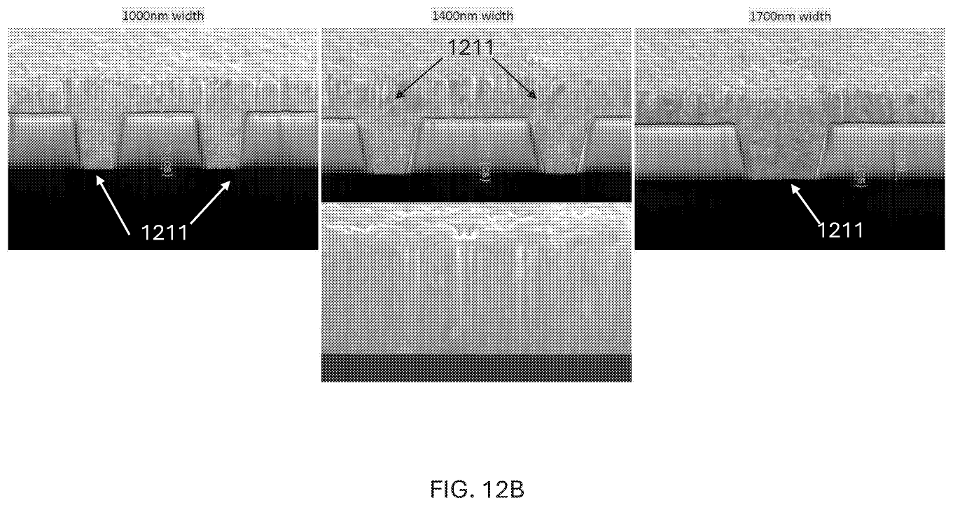

FIG. 12A shows the via filling capability of grain engineered copper with 10 mL/L of Component (B1), 6 mL/L of Component (C), and 9 mL/L of Component (D). Plating was done at 3ASD. As shown in FIG. 12A, fine grain copper was formed in vias 1211 of varying sizes (e.g., 1000 nm, 1400 nm, and 1700 nm). The formation of the fine grain copper may not be affected by the width of the via 1211. Nano voids may occur on the via wafer but not on the blanket wafer due to the surface conditions and feature size of the wafer.

FIG. 12B shows the via filling capability of grain engineered copper with 10 mL/L of Component (B2), 1 mL/L of Component (C), and 5.6 mL/L of Component (D). Plating was done at 3ASD. As shown in FIG. 12B, fine grain copper was formed in vias 1211 of varying sizes (e.g., 1000 nm, 1400 nm, and 1700 nm). The formation of the fine grain copper may not be affected by the width of the via 1211. Nano voids were not observed. Compared to FIG. 12B, the grain engineered copper in FIG. 12B shows improved via filing capabilities.

The grain engineered copper may also have a low level of impurities. Impurities may include, but are not limited to, one or more of carbon, nitrogen, sulfur, chloride, and/or oxygen. For example, the amount of impurities in the grain engineered copper may be less than 150 ppm, preferably less than 100 ppm, more preferably less than 80 ppm, or more preferably less than 50 ppm. For example, the amount of impurities in the grain engineered copper may be less than 30 ppm or less than 10 ppm.

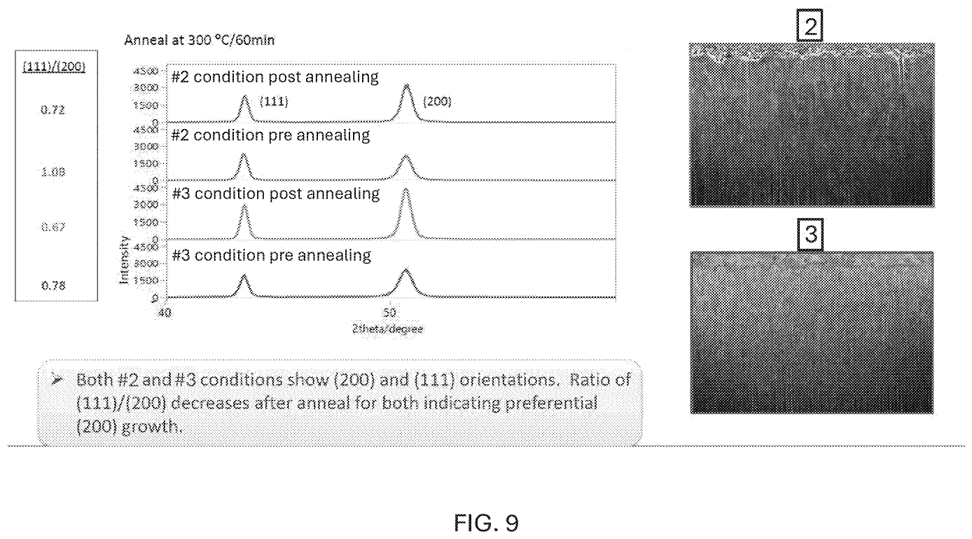

FIG. 9 shows crystal plane orientation determined by X-ray diffraction for two samples #2 and #3 (shown in FIGS. 8B and 8C and on the right of FIG. 9) of fine grain engineered copper using the compositions disclosed herein. As shown in FIG. 9, the fine grain engineered copper may exhibit a combined crystal plane (200) and (111) orientation compared to conventional copper which has a primarily (111) orientation. After annealing at 300 °C for 60 minutes, the ratio of (111)/(200) may decrease for the fine grain engineered copper. However, even after annealing the fine grain engineered copper may still exhibit a combined crystal plane (200) and (111) orientation, unlike conventional copper which transitions fully to (111) orientation after annealing. In contrast, the fine grain engineered copper may exhibit a preferentially for (200) growth following annealing as shown in FIG. 9. The quantities of crystal plane orientations described herein may be exhibited using X-ray diffraction.

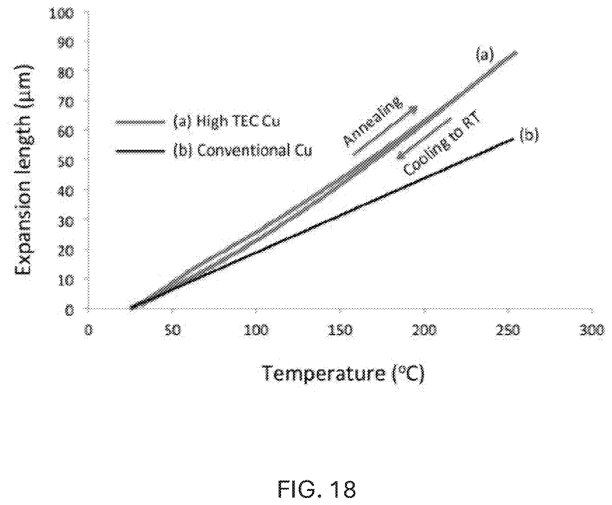

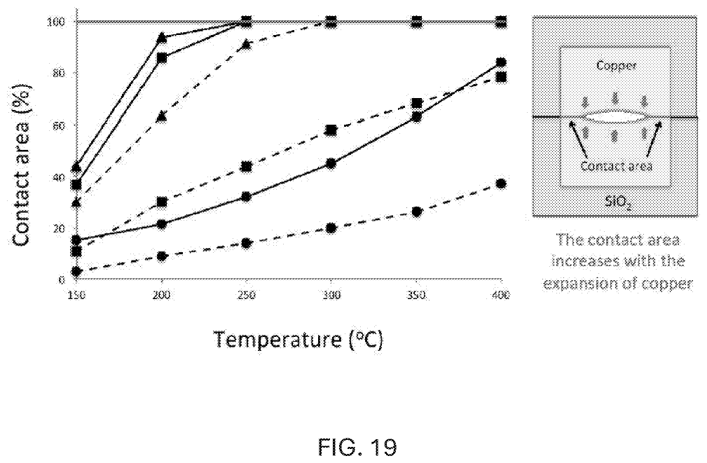

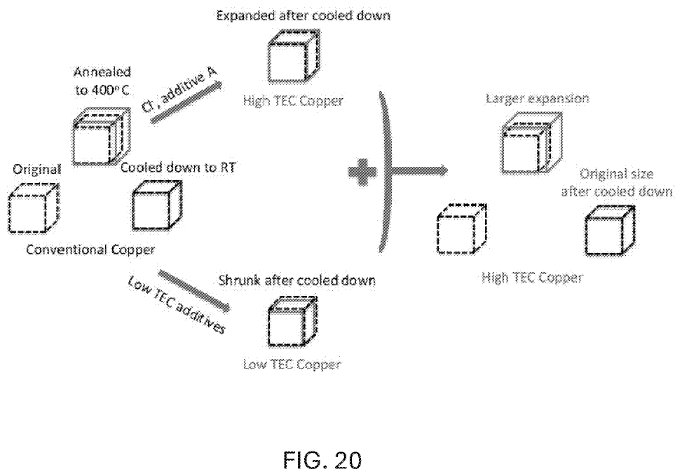

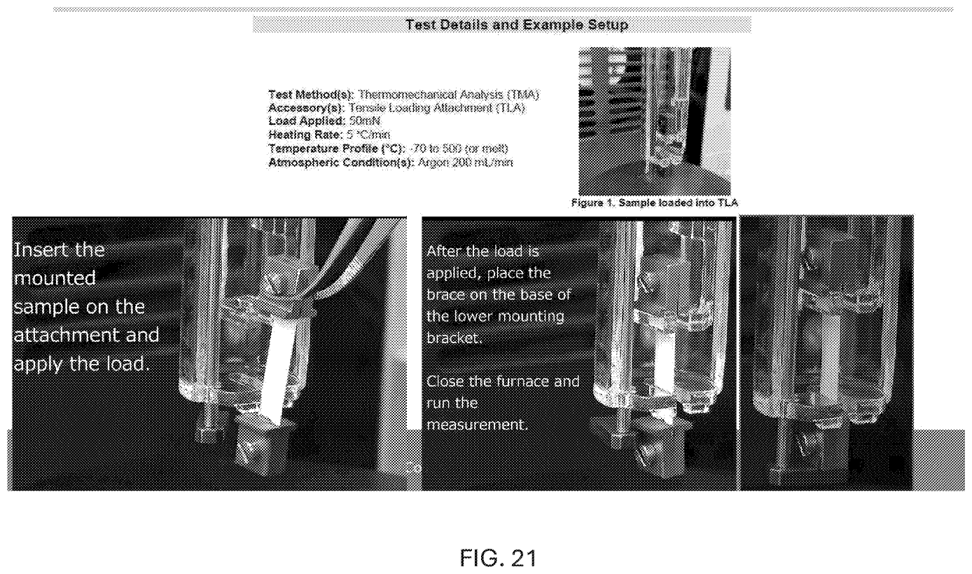

The grain engineered copper may be used for copper to copper direct bonding in semiconductor manufacturing. The grain engineered copper may exhibit improved Cu—Cu direct bonding capabilities. Without being tied to a particular theory, this may be due in part to the grain engineered copper having a high thermal expansion coefficient (TEC) (also referred to as the coefficient of thermal expansion (CTE). Because the grain engineered copper may have a high TEC it may expand during annealing, which may reduce the number of voids and thus provide improved annealing. FIGS. 18-20 illustrate the thermal expansion of high TEC copper compared to conventional copper during annealing. FIG. 21 is an illustration of coefficient of thermal expansion (CTE) measuring method using a C-Therm Tal.

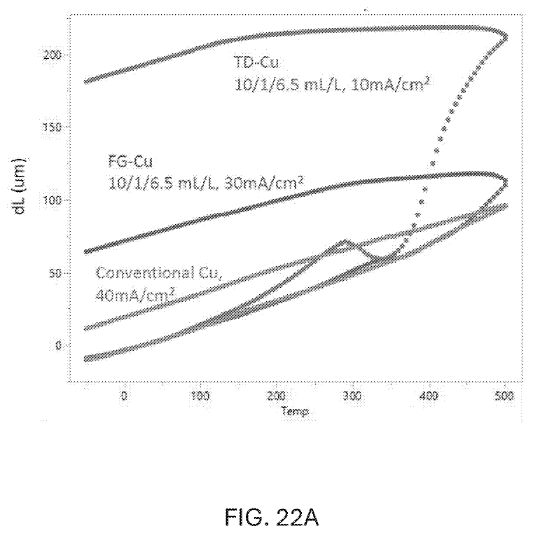

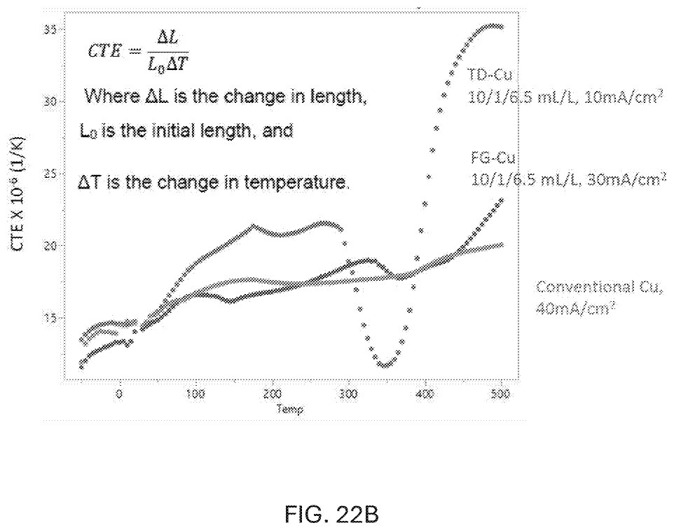

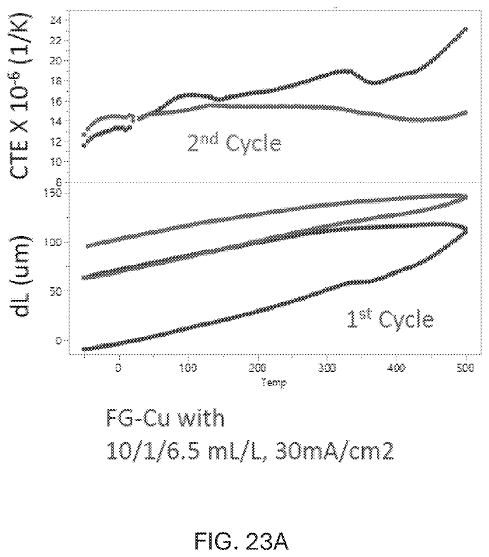

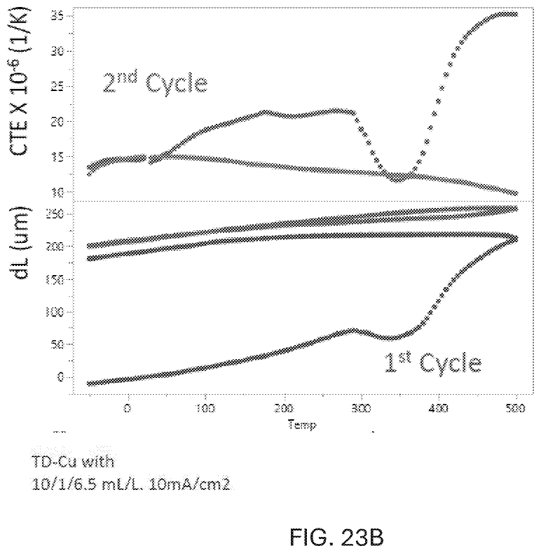

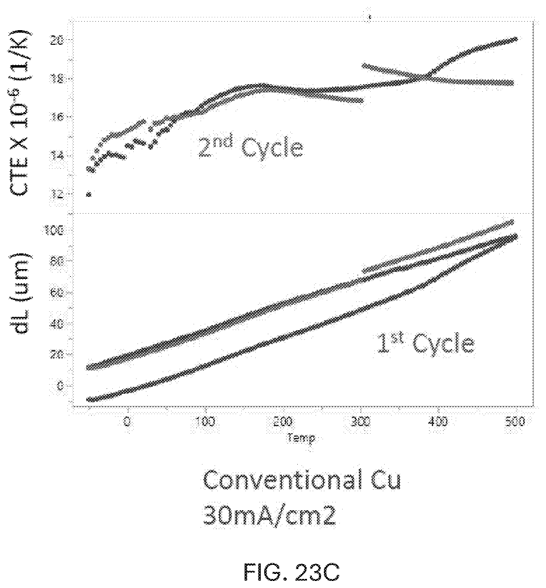

FIGS. 22A-22B are graphs showing change in length (FIG. 22A) and CTE (FIG. 22B) as a function of temperature for conventional copper, grain engineered fine grain copper (FG-Cu), and grain engineered thermal dynamic copper (TD-Cu) (also referred to herein as meta-stable Copper). FIGS. 23A-23C are graphs showing the change in length and CTE as a function of temperature for grain engineered thermal dynamic copper (TD-Cu) (FIG. 23A), grain engineered fine grain copper (FG-Cu) (FIG. 23B), and conventional copper (FIG. 23C) for two serial heating/cooling cycles. The cooling point data was also collected and the measurement was repeated twice (Heat→Cool→Heat→Cool). Hysteresis may be different between samples and/or heating/cooling cycles. As shown in FIGS. 22A and 22B and 23A-23C, TD-Cu or metal-stable Cu at 10 mA/cm² may show a higher CTE compared to FG-Cu at 30 mA/cm². Component (B) may also play a role in the change in length of the FG-Cu and/or TD-Cu. As shown in FIGS. 23A-23C, the CTE of TD-Cu and FG-Cu may be higher than that of conventional copper.

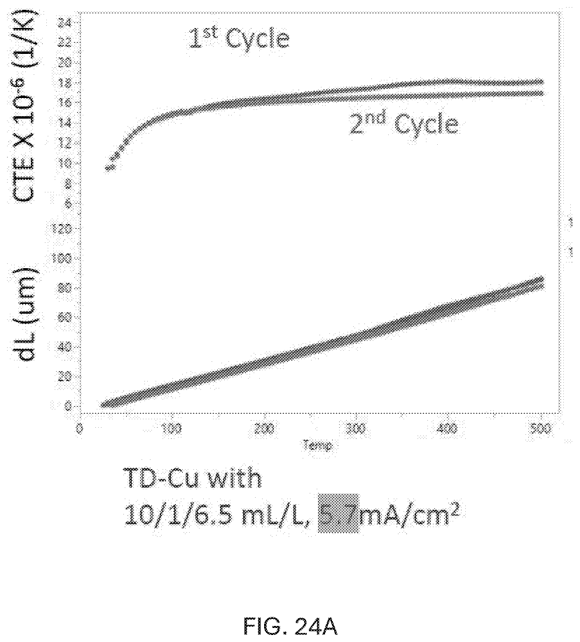

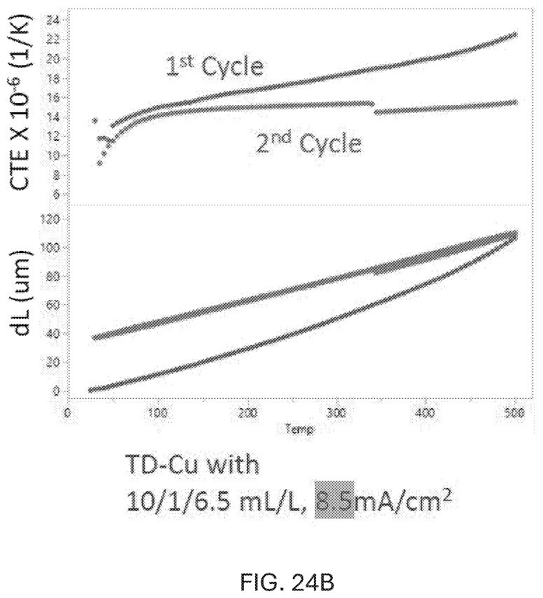

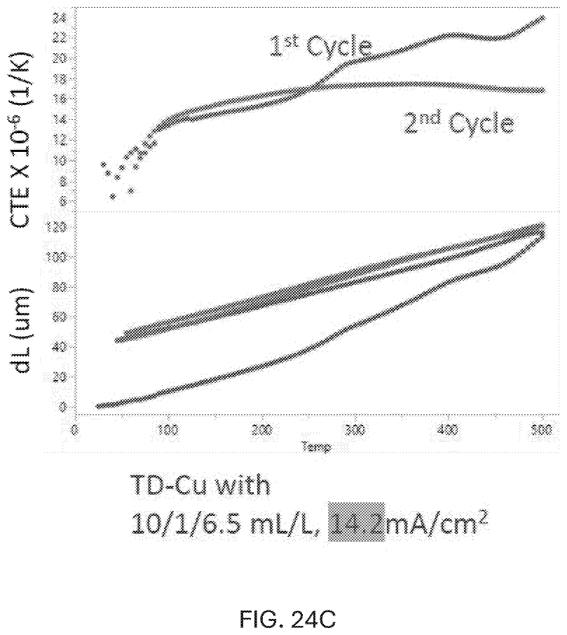

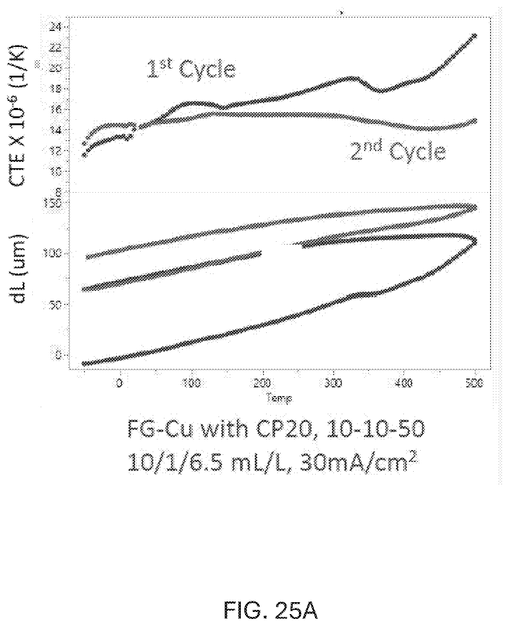

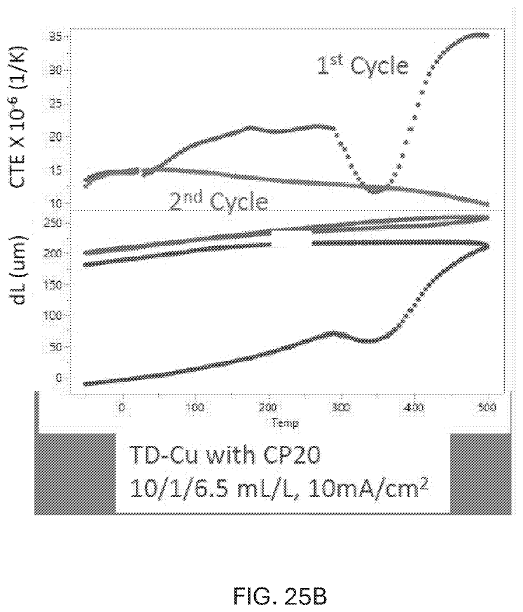

FIGS. 24A-C and 25A-B show additional CTE data for TD-Cu and FG-Cu after plating at different current densities (FIGS. 24A-C) and with different VMS concentrations (FIGS. 24A-C vs. FIG. 25A-B). The cooling point data was also collected and the measurement was repeated twice (Heat→Cool→Heat→Cool). Hysteresis may be different between samples. Where the plating bath included a VMS concentration of 40 g/L Cu (A-1), 10 g/L sulfuric acid (A-2), and 50 ppm Cl (A-3) (FIG. 24A-C), the current density may affect the CTE of the resulting electroplated copper. For example, copper plated with a higher current density, 14.2 mA/cm² (FIG. 24C) showed a higher CTE than copper plated with lower current densities, 5.7 mA/cm² (FIG. 24A) and 8.5 mA/cm² (FIG. 24B). Compared with the Cu plated with 10-10-50 VMS (FIG. 25A-B), the CTE of the plated FG-Cu (at 30 mA/cm²) (FIG. 25A) was similar but different from the plated TD-Cu (at 10 mA/cm²) (FIG. 25B). These results suggest that the concentration of Component (A) (e.g., the VMS) may play a role in the CTE of the resulting electroplated grain engineered copper.

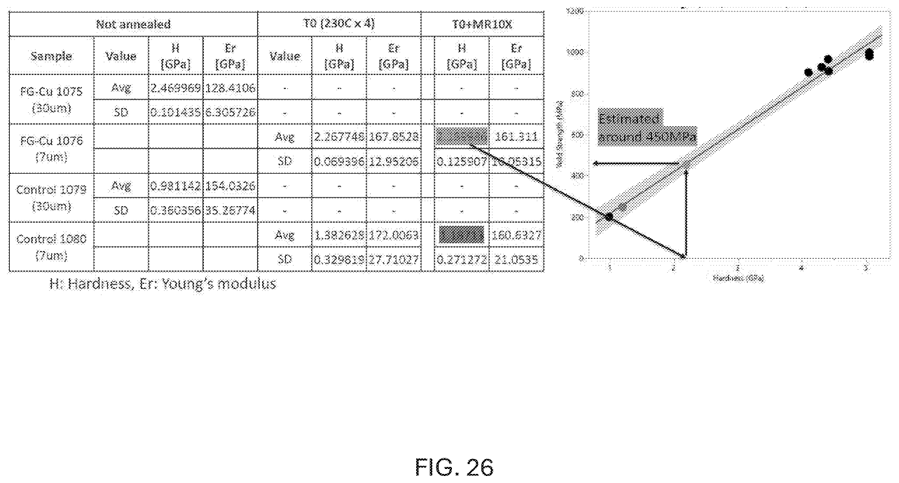

FIG. 26 shows the results of hardness by nanoindentation for grain engineered fine grain copper (FG-Cu) compared to conventional copper controls plated at a thickness of 30 μm and 7 μm before and after annealing at 230 °C. The yield strength (right graph) was estimated from reference Cu data (Hardness vs Yield Strength). The FG-Cu showed almost two times higher hardness (and yield Strength) compared to conventional control copper.

### Hybrid Bonding Using Grain Engineered Copper

The grain engineered grain copper disclosed herein may allow for the control of mechanical properties of copper interconnections in hybrid bonding. The hybrid bonding may include hybrid bonding of a plurality of dies having copper interconnections. The plurality of dies may be attached on wafers and the hybrid bonding may be used for wafer-to-wafer connections. Instead of, or in addition to, wafer-to-wafer connections, the connections may be wafer-to-die and/or die-to-die connections. The methods and compositions described herein may allow for hybrid bonding with a controlled grain structure.

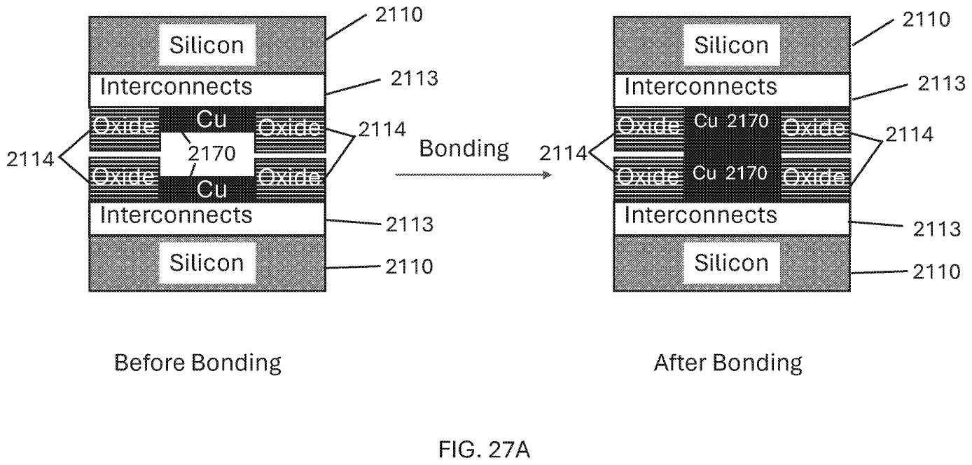

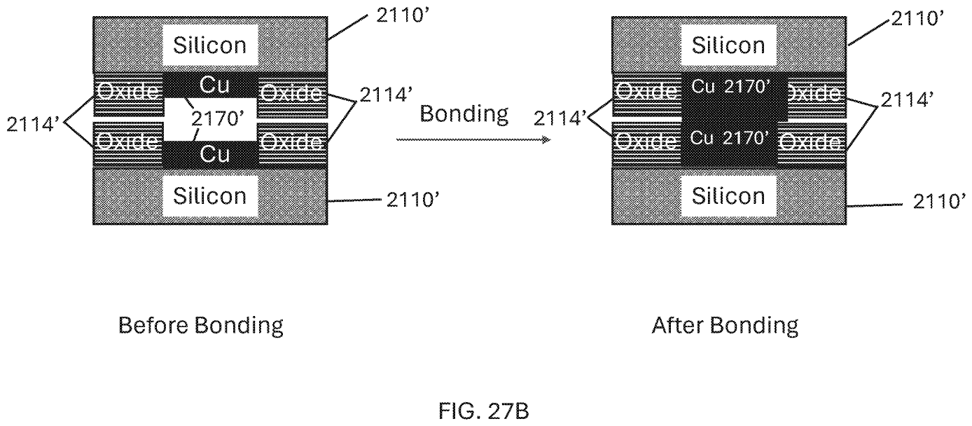

FIGS. 27A and 27B show schematics of hybrid bonding. Hybrid bonding, which may also be referred to herein as a direct bond interconnect (DBI), is a bond that can be used to vertically connect wafers, dies, chips, and/or wafers-to-dies via an embedded metal pad (e.g., a copper metal pad). The bond may be permanent. Hybrid bonding may use a combination of metal and dielectric materials to create electrical and mechanical connections between wafers, dies, chips, and/or wafers-to-dies. Hybrid bonding may combine a dielectric bond (e.g., SiOx) with an embedded metal pad 2170 (e.g., a copper metal pad) to form one or more interconnections. For example, as shown in FIG. 27A, a die 2110 and/or wafer can be formed to have a plurality of copper metal pads 2170 that can be connected to one or more copper interconnections 2113. The copper metal pads 2170 may be spaced apart by a plurality of insulator areas 2114. The insulator areas 2114 may include materials exhibiting insulating properties. For example, the insulator material may include, but is not limited to, silicon dioxide crystals, glass, polymers, gallium nitride, and/or silicon nitride. Alternatively, as shown in FIG. 27B, a die 2110′ and/or wafer can be formed to have a plurality of copper metal pads 2170′ disposed on (e.g., connected to) the die 2110′ and/or wafer itself. The copper metal pads 2170′ may be spaced apart by a plurality of insulator areas 2114′ as described above.

The copper metal pads 2170/2170′ may be made using any of the compositions and methods disclosed herein. The copper metal pads 2170/2170′ may be made using the plating baths disclosed herein. For example, the plating bath used to make the copper metal pads 2170/2170′ may include at least one of Components (A), (B), (C), (D), and/or (E).

The copper metal pads 2170/2170′ may have a concentration of bromine (Br) ions in the range of about 0.2 ppm to about 250 ppm. For example, the concentration of bromine (Br) ions may be in the range of about 0.2 ppm to about 250 ppm, about 0.4 ppm to about 240 ppm, about 0.6 ppm to about 230 ppm, about 0.8 ppm to about 220 ppm, about 1 ppm to about 210 ppm, or about 2 ppm to about 200 ppm, including all values in between. For example, the copper metal pads 2170/2170′ may have a concentration of bromine (Br) ions of about 0.2 ppm, about 0.5 ppm. about 1 ppm, about 5 ppm, about 10 ppm, about 15 ppm, about 20 ppm, about 25 ppm, about 30 ppm, about 35 ppm, about 40 ppm, about 45 ppm, about 50 ppm, about 55 ppm, about 60 ppm, about 65 ppm, about 70 ppm, about 75 ppm, about 80 ppm, about 85 ppm, about 90 ppm, about 95 ppm, about 100 ppm, about 150 ppm, about 200 ppm, or about 250 ppm, including all values in between.

The copper metal pads 2170/2170′ may exhibit any of the material characteristics described herein. For example, the copper metal pads 2170/2170′ may be made of the grain engineered copper disclosed herein. The copper metal pads 2170/2170′ may be made of the fine grain copper (FG-Cu) disclosed herein. The grain engineered copper metal pads 2170/2170′ may have a grain size of about 1 nm to about 500 nm or about 5 nm to about 500 nm. For example, the FG-Cu may have a grain size of about 5 nm, about 10 nm, about 20 nm, about 30 nm, about 40 nm, about 50 nm, about 60 nm, about 70 nm, about 80 nm, about 90 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, or about 900 nm, including all values in between.

The grain engineered copper metal pads 2170/2170′ may have an average grain size of about 5 nm to about 100 nm. For example, the grain engineered copper metal pads 2170/2170′ may have an average grain size of about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, or about 100 nm, including all values in between.

The arrangement of the grain engineered copper metal pads 2170/2170′ may exhibit a pitch. The pitch may be about 20 μm to about 10 nm. For example, the pitch may be less than about 20 μm, less than about 10 μm, less than about 5 μm, less than about 1 μm, less than about 500 nm, less than about 200 nm, less than about 100 nm, less than about 50 nm, less than about 20 nm, or less than about 10 nm, including all values in between. For example, the pitch may be between about 1 μm and about 10 μm, for example about 1 μm, about 2 μm, about 3 μm, about 4 μm, about 5 μm, about 6 μm, about 7 μm, about 8 μm, about 9 μm, or about 10 μm. In yet another example, the pitch may be between about 1 μm and 50 nm. For example, the pitch may be about 50 nm, about 60 nm, about 70 nm, about 80 nm, about 90 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 950 nm, or about 1 μm, including all values in between.

Chemical-Mechanical Planarization (CMP), and/or additional processing steps (e.g., post plate cleaning and/or rising and/or post CMP cleaning and/or rinsing), may be performed on the grain engineered copper metal pads and/or the insulator areas to achieve a relative height difference between the grain engineered copper metal pads and the insulator areas on a die and/or wafer. For example, the insulator areas 2114/2114′ may be taller than the grain engineered copper metal pads 2170/2170′, as shown in FIGS. 27A and 27B. Alternatively, the grain engineered copper metal pads 2170/2170′ may be taller than the insulator areas 2114/2114′. The relative height difference between the grain engineered copper metal pads 2170/2170′ and the insulator areas 2114/2114′ may be about 1 nm to about 300 nm. For example, the relative height difference between the grain engineered copper metal pads 2170/2170′ and the insulator areas 2114/2114′ may be about 1 nm, about 2 nm, about 3 nm, about 4 nm, about 5 nm, about 6 nm, about 7 nm, about 8 nm, about 9 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 150 nm, about 200 nm, about 250 nm, or about 300 nm, including all values in between.

Prior to bonding, the dies 2110/2170′ may be brought into contact with each other such that the grain engineered copper metal pads 2170/2170′ are in contact or the insulator areas 2114/2114′ are in contact. In some cases, in the contacting step, the grain engineered copper metal pads 2170/2170′ of opposing dies 2110/2170′ may not be in contact as shown in FIGS. 27A and 27B. For example, when the insulator areas 2114/2114′ include a silicon water material (e.g., silicone dioxide), the insulator areas 2114/2114′ may be in contact while the grain engineered copper metal pad surfaces are recessed relative to the surrounding surface of the insulator areas 2114/2114′. Alternatively, in the contacting step, the insulator areas 2114/2114′ of opposing dies 2110/2170′ may not be in contact. For example, when the insulator areas 2114/2114′ include a polymeric material, the insulator area surfaces may be recessed relative to the grain engineered copper metal pad surfaces of a die 2110/2170′ and the grain engineered copper metal pad surfaces may be in contact with the grain engineered copper metal pads 2170/2170′ of the opposed die 2110/2170′.

The contacted dies 2110/2170′ may then be annealed at an annealing temperature for a period of time. For example, the annealing temperature may be about 100 °C to about 350 °C. For example, the annealing temperature may be about 100 °C, about 150 °C, about 200 °C, about 250 °C, about 300 °C, or about 350 °C, including all values in between. The period of time may be about 5 minutes to about 2 hours, for example between about 30 minutes and about 90 minutes. The grain engineered copper may be tailored to anneal at a specific temperature as a result of the chemistry of the plating bath and/or the applied current density during plating as described herein. Alternatively, in some instances, the period of time can be less than about 5 minutes, for example, less than about 1 minute, less than about 30 seconds, or as short as 5 seconds. In yet other instances, the period of time can be longer than about 2 hours, e.g., longer than about 3, 4, 5 or 6 hours.

After annealing, the grain engineered copper metal pads 2170/2170′ may be in contact and the insulator areas 2114/2114′ may be in contact as shown in FIGS. 27A and 27B. The grain engineered copper metal pads 2170/2170′ and the insulator areas 2114/2114′ may be in contact following annealing regardless of the initial configuration (e.g., whether the grain engineered copper metal pads 2170/2170′ were initially recessed or whether the insulator areas 2114/2114′ were initially recessed).

After annealing, the grain engineered copper metal pads 2170/2170′ may exhibit a growth in grain size as described herein. The change (e.g., growth) in grain size of the grain engineered copper metal pads 2170/2170′ following annealing may range from about 5 nm to about 100 μm. For example, following annealing, the grain size of the grain engineered copper metal pads 2170/2170′ may increase by about 5 nm, about 10 nm, about 15 nm, about 20 nm, about 25 nm, 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 950 nm, about 1 μm, about 5 μm, about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm, or about 100 μm, including all values in between.

For example, the grain engineered copper metal pads 2170/2170′ may be fine grain (e.g., about 1 nm to about 500 nm, or about 5 nm to about 500 nm) after plating and then following annealing, the grain engineered copper metal pads 2170/2170′ may grow to large grain (e.g., greater than 1 μm). For example, upon annealing, the grains may grow from an initial size (e.g., fine grain) to a larger size (e.g., large grain). In this embodiment, following annealing, the grain engineered copper metal pads 2170/2170′ may have a second grain size of about 1 μm to about 200 μm. For example, the following annealing the deposited grain engineered copper metal pads 2170/2170′ may have a grain size of about 1 μm, about 5 μm, about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm, about 100 μm, about 150 μm, or about 200 μm, including all values in between.

In another example, the grain engineered copper metal pads 2170/2170′ may be fine grain after plating and remain fine grain following annealing. In this embodiment, the grain size of the grain engineered copper metal pads 2170/2170′ following annealing may still increase in size. However, the grain size of the grain engineered copper metal pads 2170/2170′ following annealing may still be fine grain (e.g., about 1 nm to about 500 nm, or about 5 nm to about 500 nm). For example, following annealing, the deposited grain engineered copper metal pads 2170/2170′ may have a second grain size that is similar to the first grain size. For example, following annealing the deposited grain engineered copper metal pads 2170/2170′ may have a grain size of about 5 nm, about 10 nm, about 20 nm, about 30 nm, about 40 nm, about 50 nm, about 60 nm, about 70 nm, about 80 nm, about 90 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, or about 900 nm, including all values in between.

The grain size of the grain engineered copper metal pads 2170/2170′ following annealing may be within about 30% to about 2% of the grain size of the grain engineered copper metal pads 2170/2170′ before annealing. For example, the grain size of the grain engineered copper metal pads 2170/2170′ following annealing may be within about 2%, about 3%, about 4%, about 5%, about 10%, about 15%, about 20%, about 25%, or about 30% of the grain size of the grain engineered copper metal pads 2170/2170′ before annealing.

In yet another embodiment, following annealing at a higher temperature (e.g., 300 °C or 350 °C), the grains of the grain engineered copper metal pads 2170/2170′ may grow to large grain (e.g., greater than 1 μm). For example, following annealing at a higher temperature, the grain size of the grain engineered copper metal pads 2170/2170′ may increase by about 5 nm, about 10 nm, about 15 nm, about 20 nm, about 25 nm, 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 150 nm, about 200 nm, about 250 nm, about 300 nm, about 350 nm, about 400 nm, about 450 nm, about 500 nm, about 550 nm, about 600 nm, about 650 nm, about 700 nm, about 750 nm, about 800 nm, about 850 nm, about 900 nm, about 950 nm, about 1 μm, about 5 μm, about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm, or about 100 μm, including all values in between.

In yet another embodiment, the electroplating solutions disclosed herein may be used to deposit grain engineered copper metal pads 2170/2170′ that anneals at a specific temperature. For example, upon annealing, the grains may grow from an initial size to a larger size, such as about the size of the space between the opposing grain engineered copper metal pads 2170/2170′, within a time shorter than two hours after the anneal temperature is applied (e.g., within a time of 5 minutes to 2 hours). In yet another example, the time to anneal may also be greater than about 2 hours (e.g., between about 2 hours and about 6 hours). In one embodiment, the grain engineered copper metal pads 2170/2170′ may anneal at a lower temperature (e.g., less than 250 °C, such as 200 °C). In another embodiment, the grain engineered copper metal pads 2170/2170′ may anneal at a higher temperature (e.g., about 200 °C to about 350 °C).

The grain engineered copper metal pads 2170/2170′ may exhibit a combined crystal plane (200) and (111) orientation compared to conventional copper pads which have a primarily (111) orientation. After annealing, the ratio of (111)/(200) may decrease for the grain engineered copper metal pads 2170/2170′. However, even after annealing the grain engineered copper metal pads 2170/2170′ may still exhibit a combined crystal plane (200) and (111) orientation, unlike conventional copper metal pads which may transition fully to (111) orientation after annealing. In contrast, the grain engineered copper metal pads 2170/2170′ may exhibit a preferential for (200) growth following annealing as described above. Preferably the grain engineered copper metal pads 2170/2170′ have a combined crystal plane orientation of (200) and (111) before and/or after annealing. However, the crystal plane orientation before and/or after annealing is not limited to (200) and (111). For example, the grain engineered copper metal pads 2170/2170′ before and/or after annealing may also exhibit another suitable crystal plane orientation, including, but not limited to, a (220), (311), and/or (222) orientation, alone or in combination, with the crystal plane orientation of (200) and/or (111).

Following annealing, the contacted grain engineered copper metal pads 2170/2170′ may be substantially defect free. For example, the contacted grain engineered copper metal pads 2170/2170′ may not show dishing and/or defects.

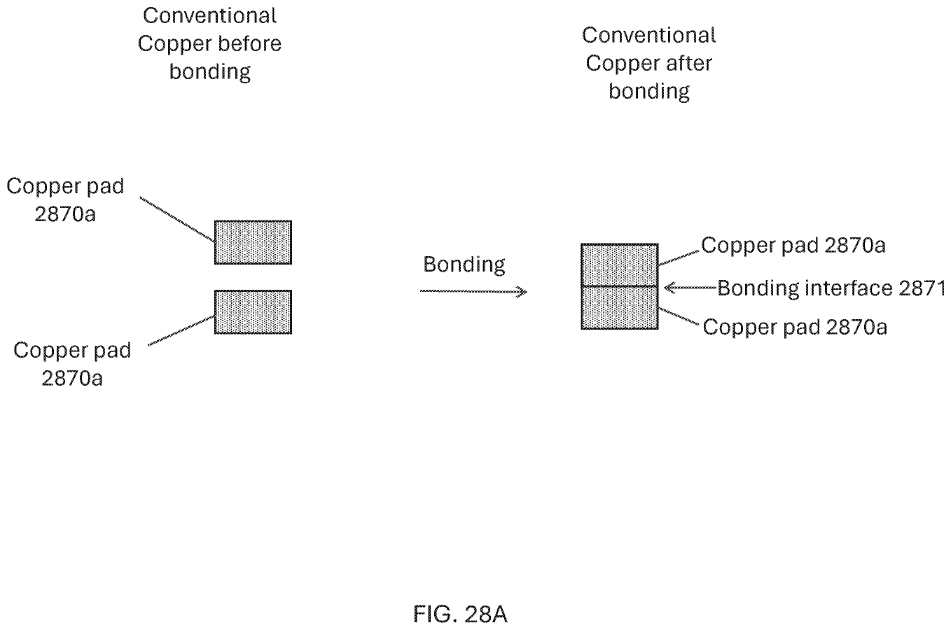

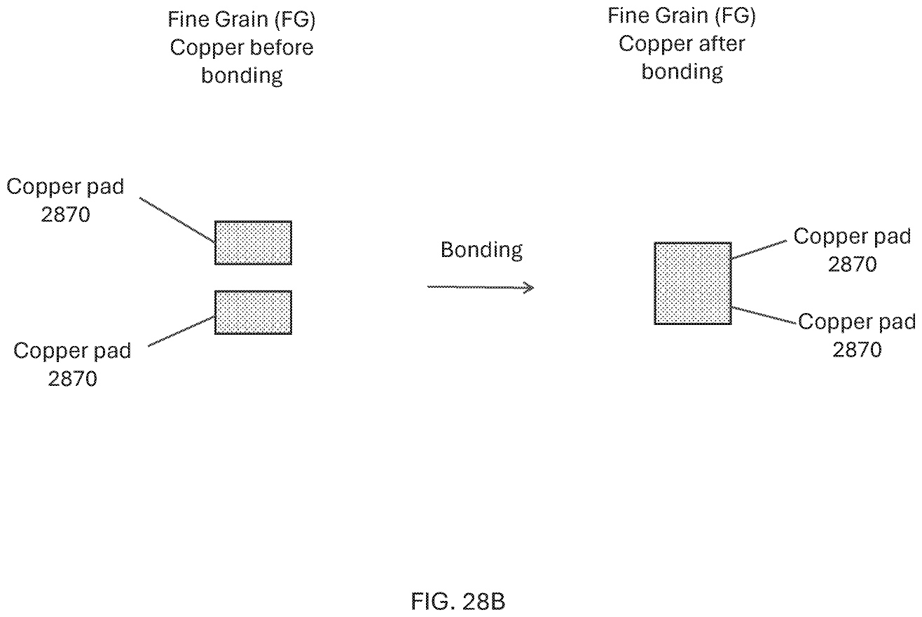

FIGS. 28A and 28B show schematics comparing conventional copper pads 2870a and grain engineered copper metal pads 2870 before and after annealing. As shown in FIG. 28A, conventional copper pads 2870a may exhibit a bonding interface 2871 between the contacted conventional copper pads 2870a following annealing. In contrast, as shown in FIG. 28B, the contacted grain engineered copper metal pads 2870 may be exhibit no interface between the contacted pads 2870. In other words, the contacted grain engineered copper metal pads 2870 may be interface free.

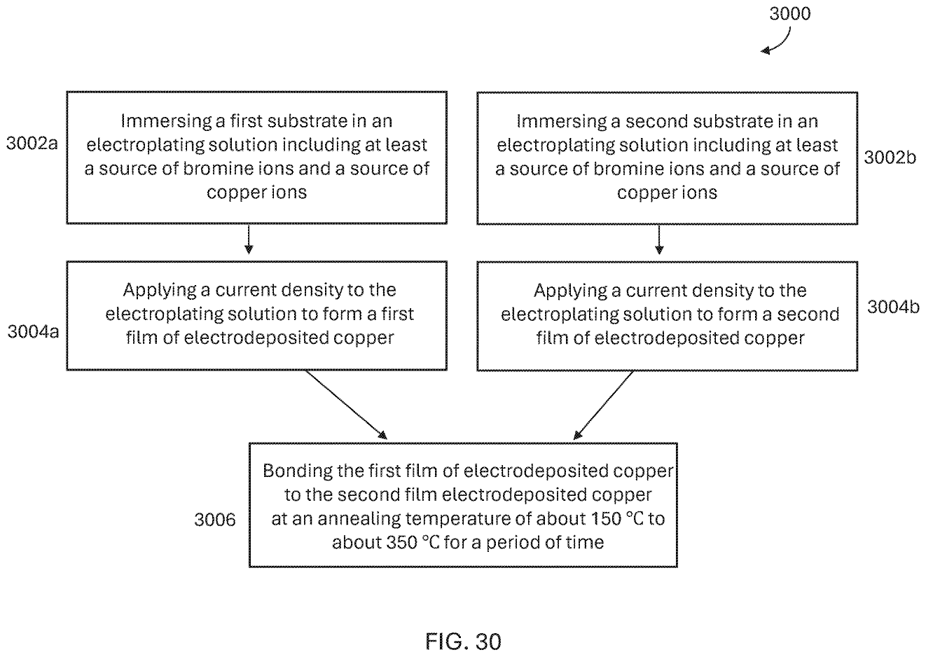

FIG. 30 shows an example method 3000 for hybrid bonding two films of electrodeposited copper according to the inventive concepts and compositions disclosed herein. The method 3000 begins at step 3002a by immersing a first substrate in an electroplating solution. Concurrently with, or following, step 3002a, at step 3002b, a second substrate may be immersed in an electroplating solution. The first and second substrates may be any of the substrates disclosed herein, for example, the substrate may include, but is not limited to, a printed circuit board, a silicon wafer, an IC substrate, or a polymer. The electroplating solution may include any of the electroplating solutions described herein. Preferably the electroplating solution includes at least a source of bromine ions and a source of copper ions. The first and second substrate may be immersed in the same electroplating solution or in different electroplating solutions.

Thereafter, at steps 3004a and 3004b (which may be performed concurrently or in sequence), a current density is applied to the electroplating solution(s) to form a first film of electrodeposited copper on the first substrate and a second film of electrodeposited copper on the second substrate. As described herein, the current density may range from about 3 mA/cm² to about 90 mA/cm². The current density may be applied for a period of time that may range from about 0.5 minutes to about 2 hours. The resulting films of electrodeposited copper may be a copper metal pad.

Once the films of electrodeposited copper are formed, the films may be ready for hybrid bonding. Thus, at step 3006, the first film of electrodeposited copper may be bonded to the second film of electrodeposited copper. As described herein, bonding may occur at an annealing temperature of about 150 °C to about 350 °C for a period of time. The period of time may be about 5 minutes to about 2 hours. After bonding, there may be no interface between the contacted first and second films of electrodeposited copper as described herein. The bonded first and second films of electrodeposited copper may also be substantially defect free.

The compositions and methods disclosed herein may be used to manufacture a hybrid bonded plurality of dies with the grain engineered copper metal pads disclosed herein. The compositions and methods disclosed herein may also be used to manufacture hybrid bonded wafer-to-die and/or die-to-die connections.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The term “about,” as used herein, refers to plus or minus ten percent of the object that “about” modifies.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of making a film of electrodeposited copper on a substrate, the method comprising:
immersing the substrate in an electroplating solution comprising:
a virgin makeup solution comprising:
a source of copper ions;
sulfuric acid; and
a source of chloride ions;
a suppressor;
an accelerator; and
a source of bromine ions; and
applying a current density to the electroplating solution,
wherein the film of electrodeposited copper has a concentration of bromine ions of about 0.2 ppm to about 250 ppm, a first crystal plane orientation of (111) and (200), and a first grain size of about 5 nm to about 500 nm.

2. The method of claim 1, further comprising:
annealing the film of electrodeposited copper for a period of time at a temperature of about 150 °C to about 350 °C,
wherein the annealed film of electrodeposited copper has a second crystal plane orientation of (111) and (200) and a second grain size that is larger than the first grain size.

3. The method of claim 2, wherein the period of time is at least one hour.

4. The method of claim 2, wherein the film of electrodeposited copper is a copper metal pad.

5. The method of claim 1, wherein the film of electrodeposited copper is a first film of electrodeposited copper, the method further comprising:
making a second film of electrodeposited copper, wherein the first film of electrodeposited copper is a first copper metal pad and the second film of electrodeposited copper is a second copper metal pad; and
bonding the first film of electrodeposited copper and the second film of electrodeposited copper at an annealing temperature of about 150 °C to about 350 °C for a period of time,
wherein there is no interface between the first copper metal pad and the second copper metal pad following the bonding.

6. The method of claim 1, wherein the substrate comprises a copper seed layer disposed on the substrate and wherein the film of electrodeposited copper is disposed on top of the copper seed layer.

7. The method of claim 1, wherein the source of bromine ions is present in the electroplating solution in an amount of about 10 ppm to about 100 ppm.

8. The method of claim 7, wherein the source of bromine ions is present in the electroplating solution in an amount of 20 ppm to about 70 ppm.

9. The method of claim 1, wherein the sulfuric acid is present in the virgin makeup solution in a concentration of about 10 g/L to about 200 g/L.

10. The method of claim 1, wherein the film of electrodeposited copper is used for hybrid bonding.

11. A copper metal pad for hybrid bonding, the copper metal pad comprising a concentration of bromine ions of about 0.2 ppm to about 250 ppm.

12. The copper metal pad of claim 11, further comprising a combination of a crystal plane orientation of (111) and (200).

13. The copper metal pad of claim 12, wherein the crystal plane orientation is (111) and (200) following annealing of the copper metal pad.

14. The copper metal pad of claim 13, wherein the copper metal pad has a first crystal plane orientation ratio of (111)/(200) before annealing and a second crystal plane orientation ratio of (111)/(200) following annealing and wherein the first crystal plane orientation ratio is different from the second crystal plane orientation ratio.

15. The copper metal pad of claim 11, further comprising a grain size of about 5 nm to about 500 nm.

16. The copper metal pad of claim 15, wherein the grain size increases following annealing at a temperature of about 150 °C to about 350 °C.

17. The copper metal pad of claim 16, wherein the copper metal pad is a first copper metal pad and further comprising a second copper metal pad contacting the first copper metal pad following the annealing, wherein there is no interface between the first copper metal pad and the second copper metal pad following the annealing.

18. The copper metal pad of claim 11, wherein the copper metal pad is embedded between one or more insulator areas.

19. The copper metal pad of claim 11, wherein the copper metal pad is connected to a substrate, the substrate comprising a wafer, a die, or a chip.

20. A hybrid bonded device, the hybrid bonded device comprising:
a first substrate and a second substrate;
a plurality of first copper metal pads on the first substrate and disposed between the first substrate and the second substrate, the plurality of first copper metal pads separated by a plurality of first insulator layers; and
a plurality of second copper metal pads on the second substrate and disposed between the first substrate and the second substrate, the plurality of second copper metal pads separated by a plurality of second insulator layers,
wherein:
each of the plurality of first copper metal pads and the plurality of second copper metal pads have a concentration of bromine ions of about 0.2 ppm to about 250 ppm;
the plurality of first copper metal pads are bonded to the plurality of second copper metal pads following annealing at a temperature of about 150 °C to about 350 °C for a period of time; and
there is no interface between the plurality of first copper metal pads and the plurality of second copper metal pads following annealing.
